(19) United States
(12) Patent Application Publication
(10) Pub. No.: US 2004/0015309 A1
(43) Pub. Date: Jan. 22, 2004

(54) Systems and methods for OTDR tracing and mapping

(76) Inventors: Douglas S. Swisher, Coon Rapids, MN (US); Brent A. Lossing, Savage, MN (US); Robert J. Galuska, Minneapolis, MN (US)

Correspondence Address: MERCHANT & GOULD PC, P.O. BOX 2903, MINNEAPOLIS, MN, 55402-0903, US

(21) Appl. No.: 10/005,219

(22) Filed: Dec. 4, 2001

Related U.S. Application Data
(60) Provisional application No. 60/251,264, filed on Dec. 4, 2000.

(51) Int. Cl. G01R 25/00

(52) U.S. Cl. 702/79

(57) ABSTRACT

An end-to-end network management package that allows a user to model and analyze a network infrastructure. A user is able to pinpoint spots on the OTDR trace and locate them in real-time on a geographical representation of the network.

### RELATED APPLICATIONS

This application claims priority of U.S. Provisional Application No. 60/251,264 filed Dec. 4, 2000 which is hereby incorporated by reference.

### BACKGROUND OF THE INVENTION

The traditional approach to asset management could only have developed in a sole source environment. It was a time when customers had no choice but to wait for service. Costs could be passed on, so there was little incentive to update management systems. Information was spotty and closely held by maintenance departments or even individuals.

Maps and diagrams were hand drawn. Tattered originals passed from hand to hand, deteriorating with time. Computerized records, if they existed, might be on a floppydisk in someone's desk drawer or the glove compartment of a maintenance vehicle.

Teams of technicians were sent out to “look around” and run—or rerun—tests. The alternative . . . rough guesses, mistaken installations and expensive rework and repair. Existing facilities went underutilized. Entire routes disappeared from memory. At great cost, delay and general inconvenience, crews plowed fiber to replace what was already in the ground waiting to be used.

In addition, the ability to relate an optical time domain reflectometer (OTDR) trace to a physical location on a geographic map in real time was not possible. The prior approach was to place a fixed X on a map based on a distance measurement entered by a user. To investigate a cable break, the user would have to plot multiple Xs which was quite cumbersome.

In today's competitive environment—with demanding customers, higher volumes and narrower margins—there is no room for delay, error, wasted manpower or under-utilized infrastructure. To meet demand and beat the competition, you have to know what you've got, where it is, who owns or leases it and how it is equipped.

It is desirable to provide a powerful, end-to-end network management package.

### SUMMARY OF THE INVENTION

A method for analyzing a network infrastructure is provided. The method includes steps of:

(a) generating a graphical representation of the network infrastructure wherein the graphical representation represents physical locations of the network infrastructure on a geographic map;

(b) testing a portion of the network infrastructure with an OTDR signal to generate an OTDR trace;

(c) displaying the OTDR trace resulting from step (b),

(A) linking a cursor position on the OTDR trace displayed in step (c) with an actual location on the graphical representation generated in step (a).

### BRIEF DESCRIPTION OF THE DRAWINGS

FIG. 1 is a schematic of the system according to a preferred embodiment of the present invention.

FIGS. 2-152 represent various screen shots of the invention.

### DETAILED DESCRIPTION OF THE PREFERRED EMBODIMENTS

The present invention is directed to a sophisticated database/mapping package designed for today's broadband environment. The system of the present invention, allows the management of all the network's assets; inside and outside plant; fiber and copper, cable and equipment. It tracks every route, every foot of conduit down to sub-ducts and individual fibers. The system allows various views of the network from a cross-country view to an individual termination panel or utility hole.

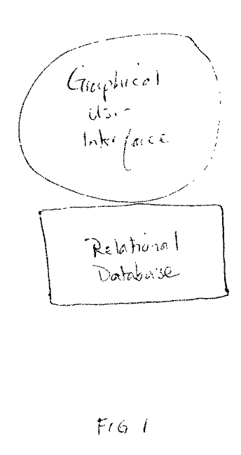

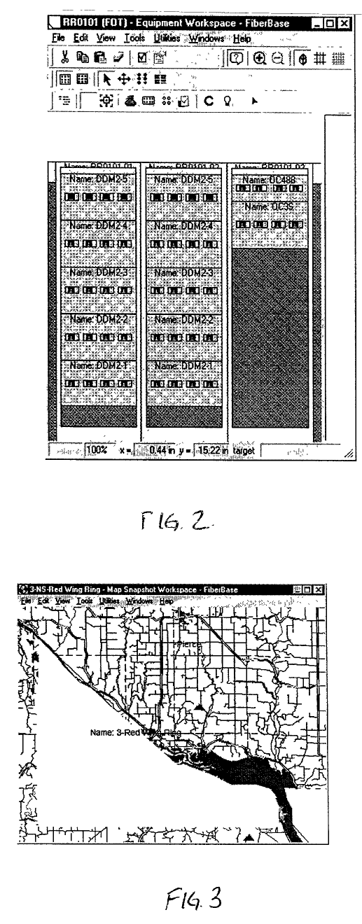

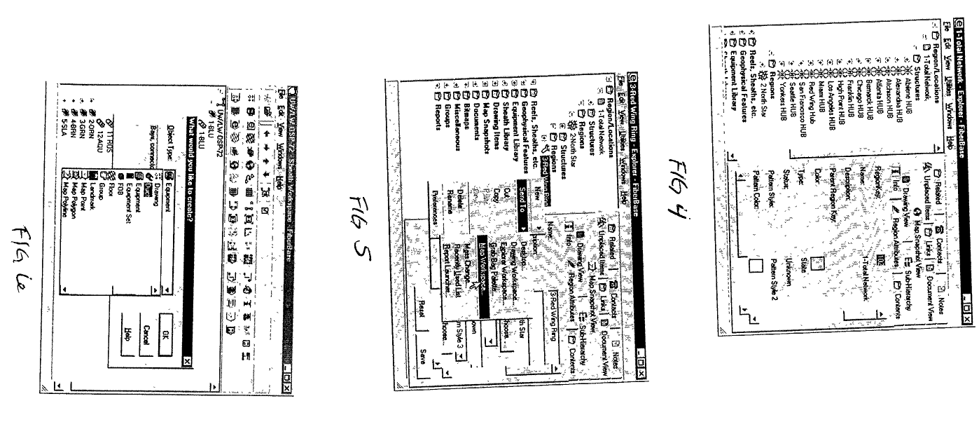

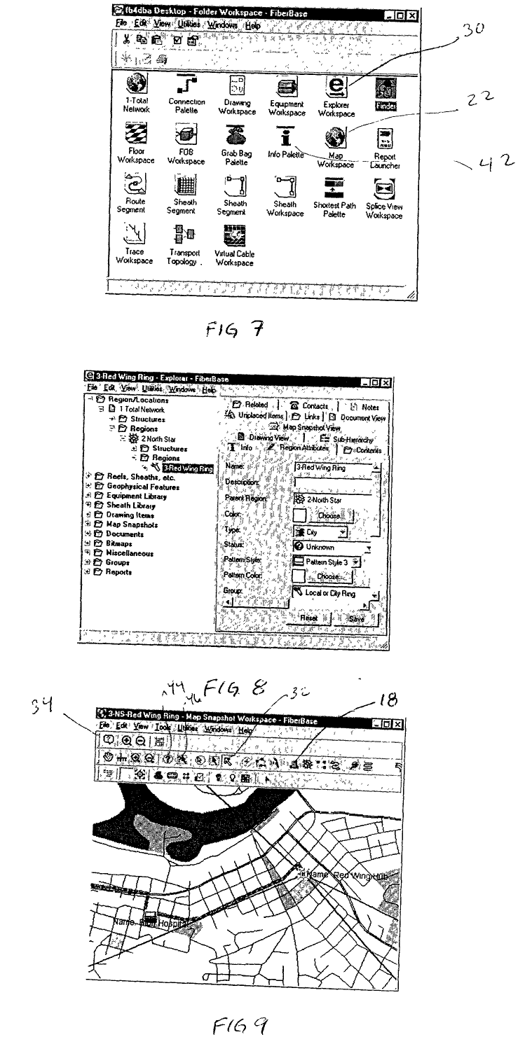

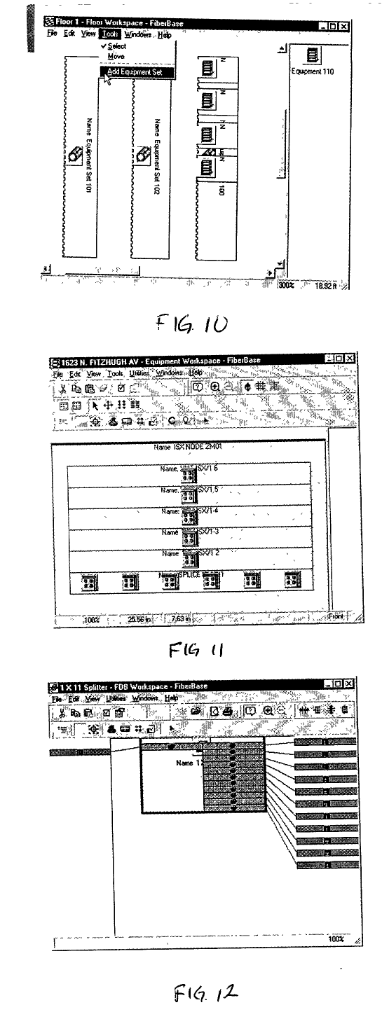

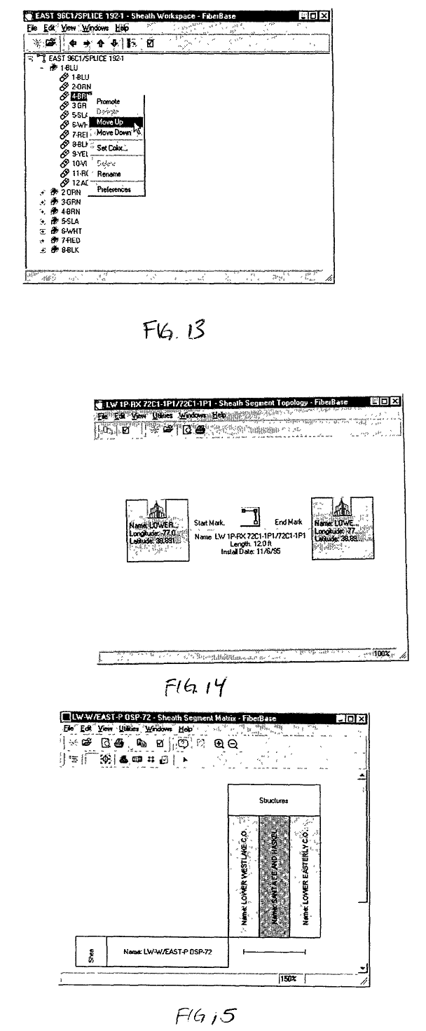

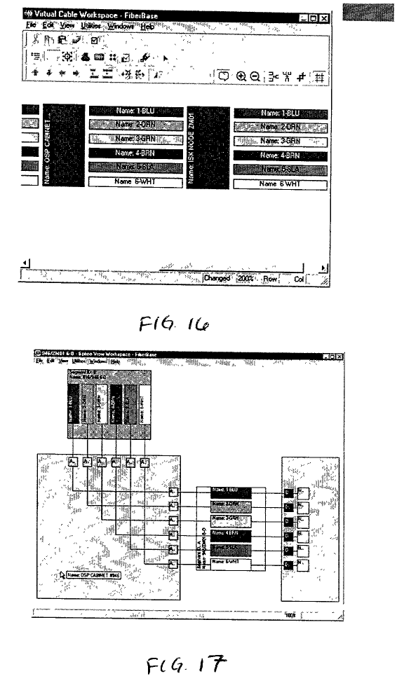

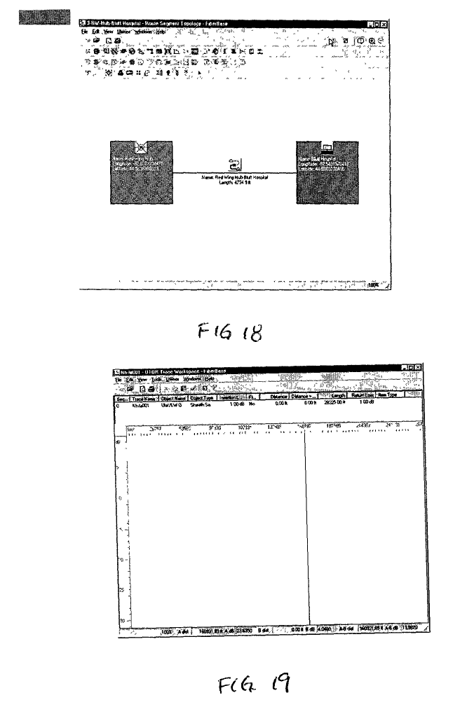

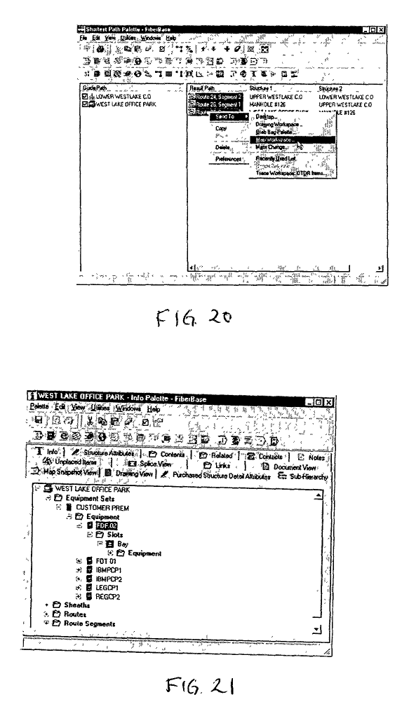

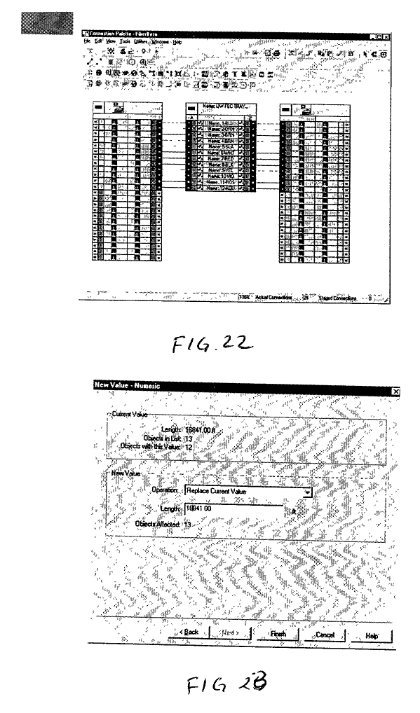

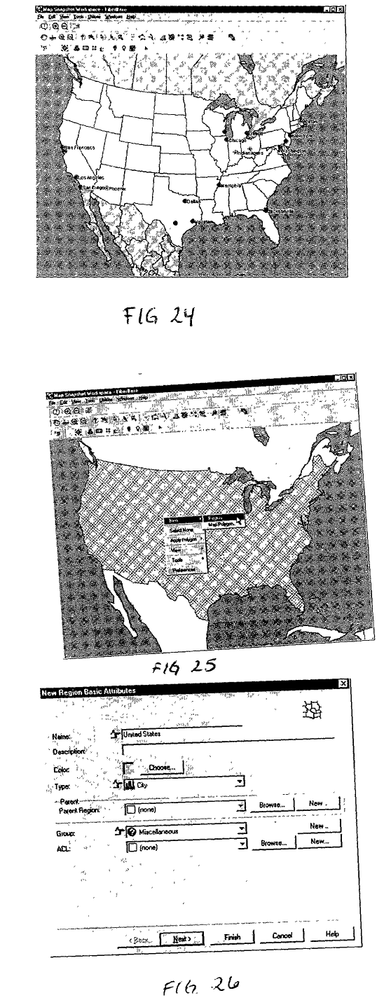

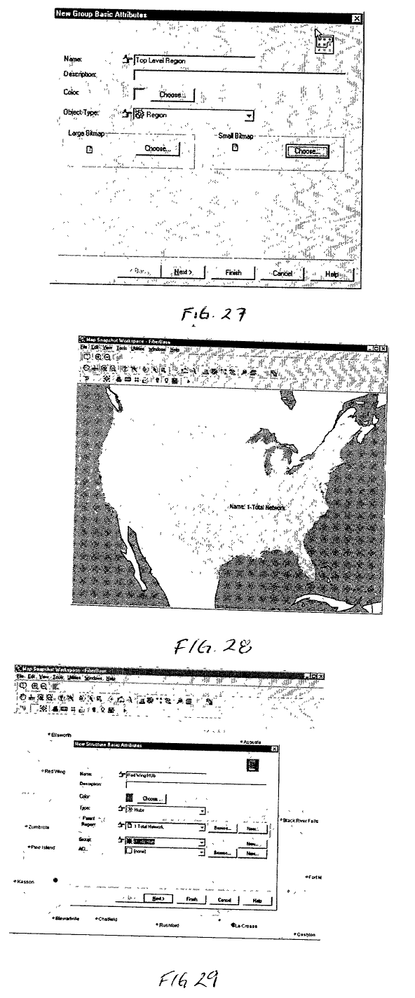

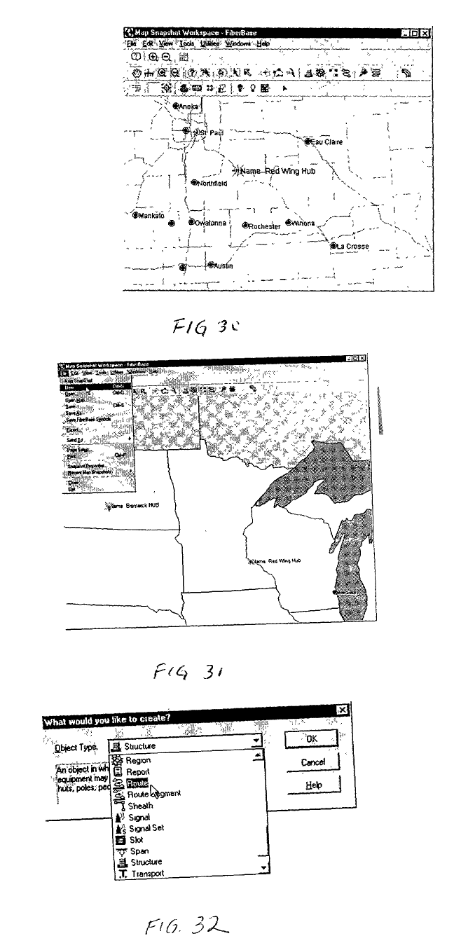

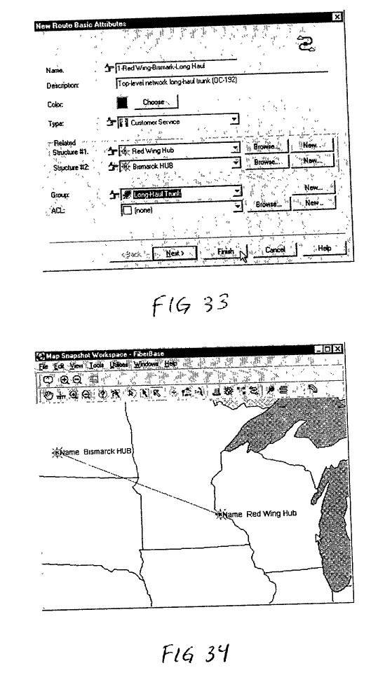

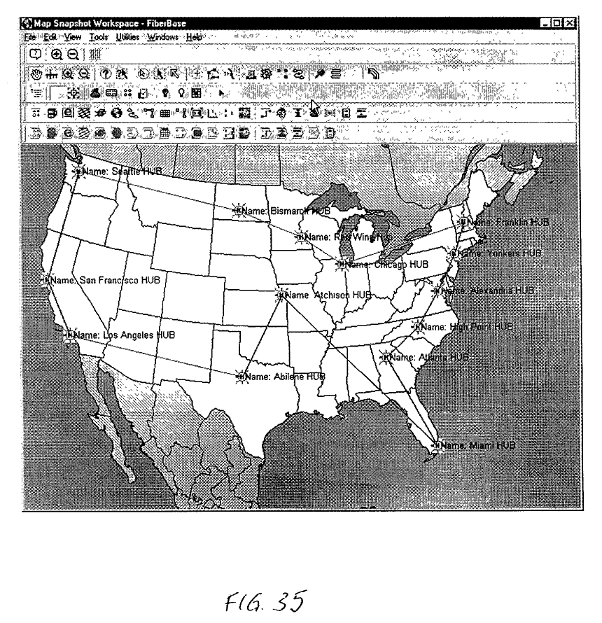

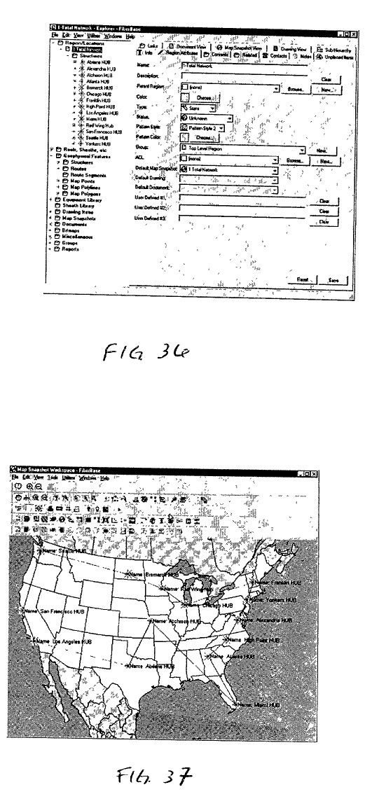

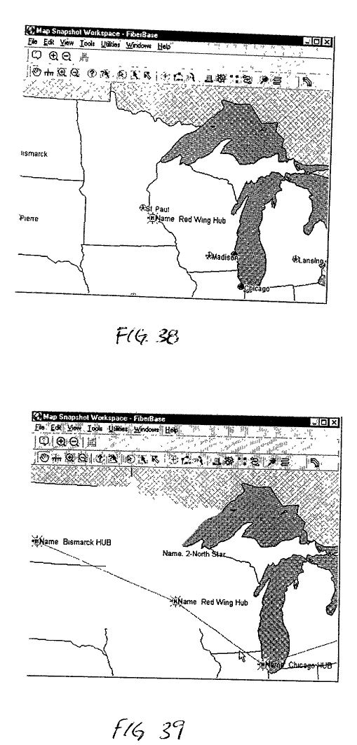

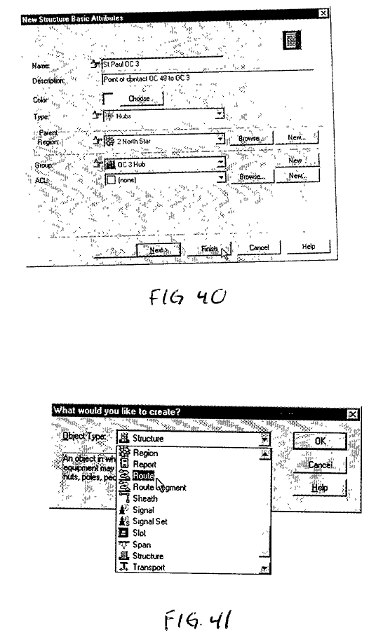

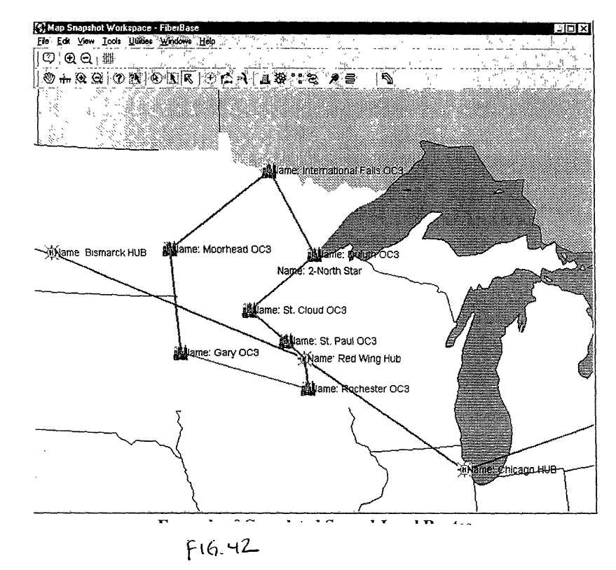

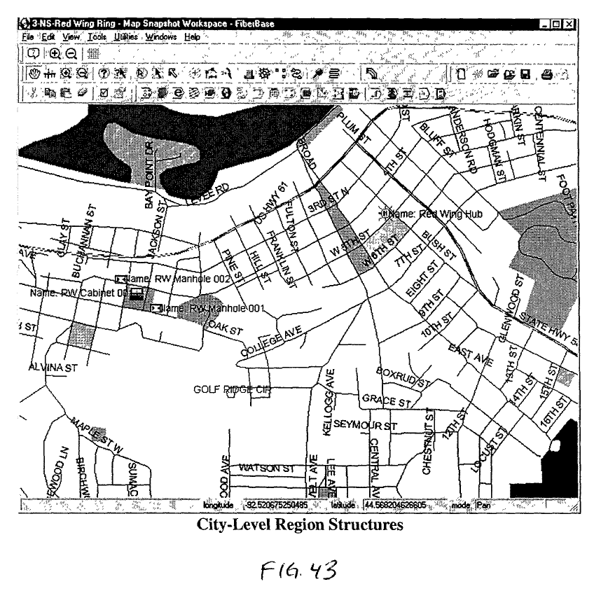

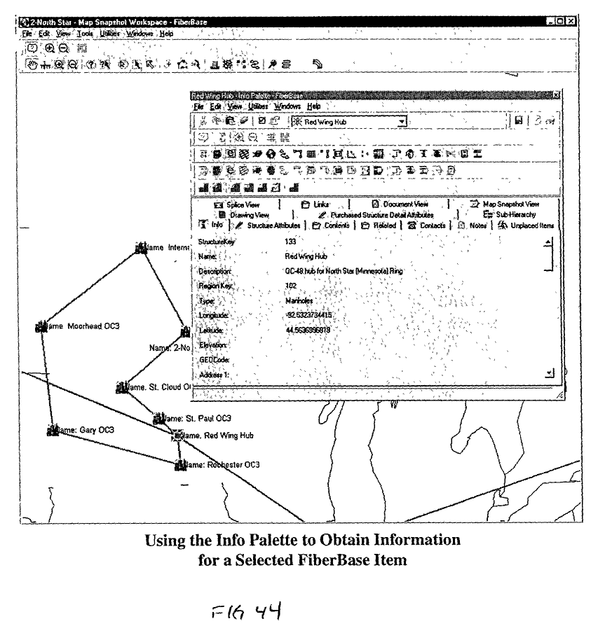

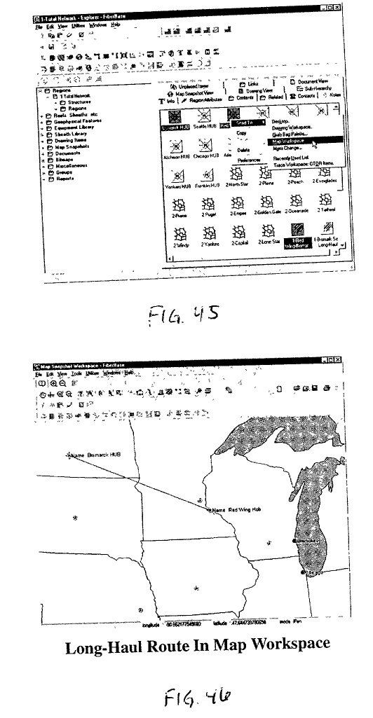

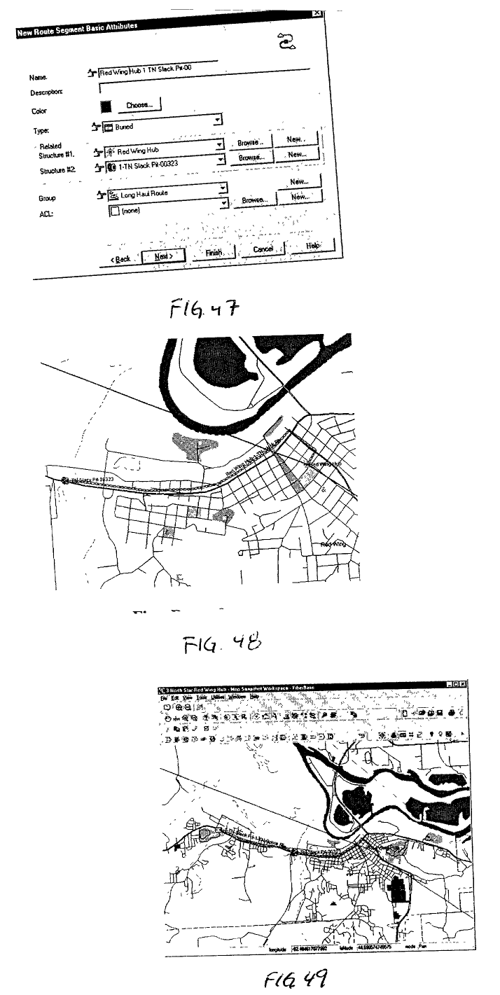

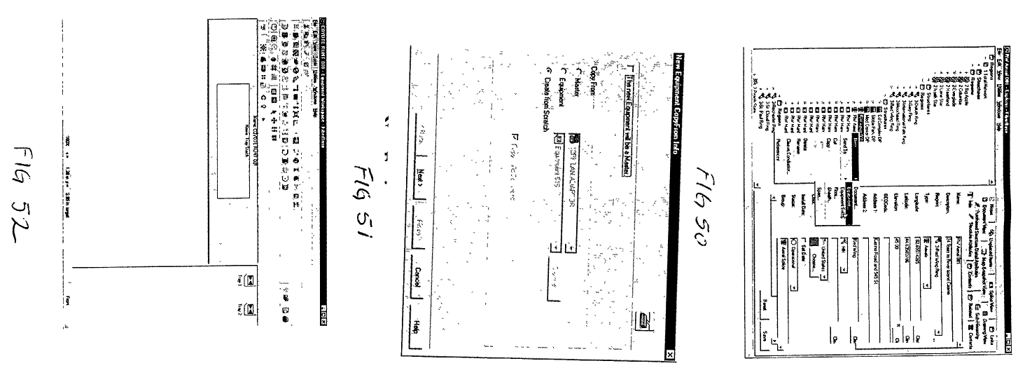

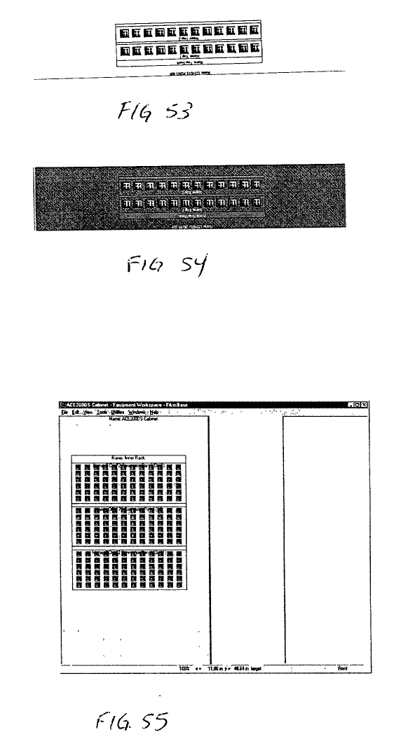

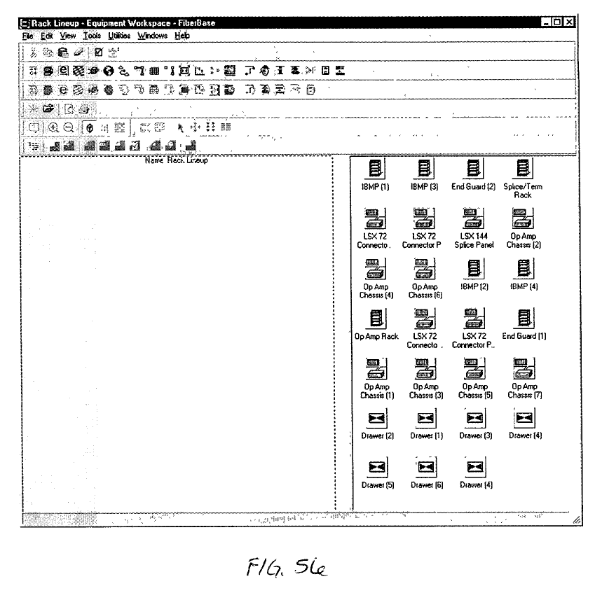

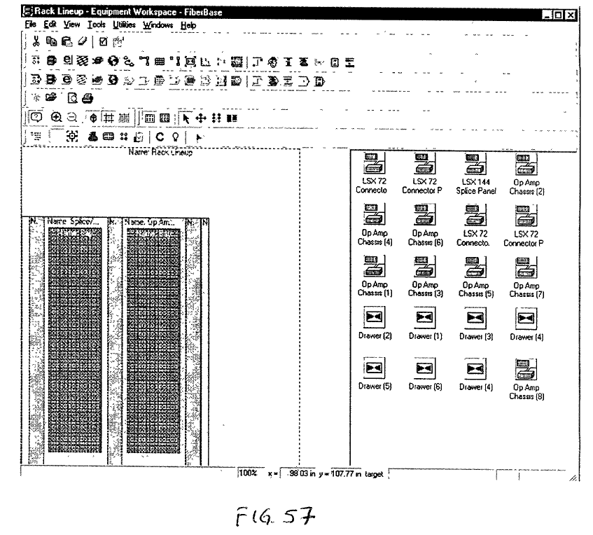

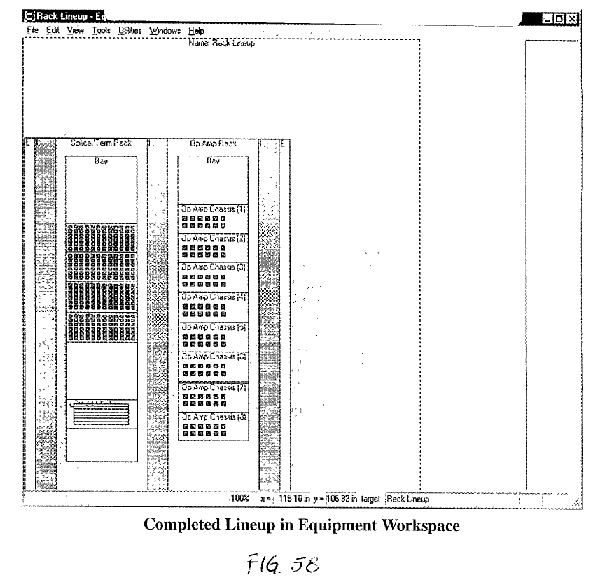

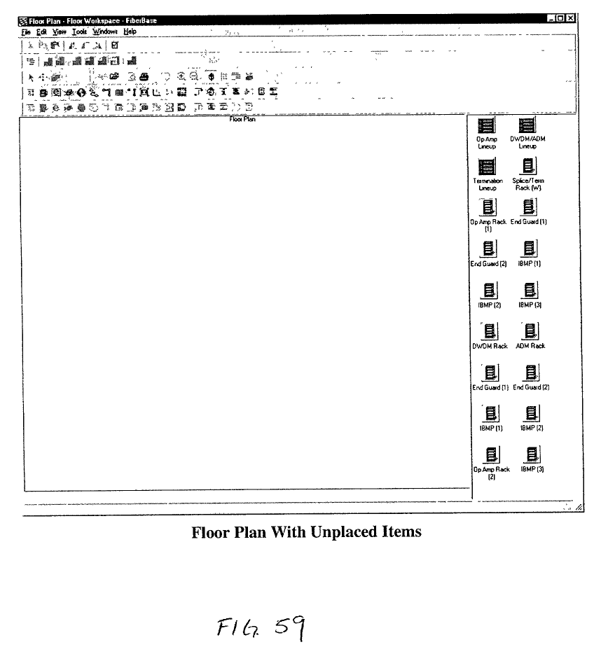

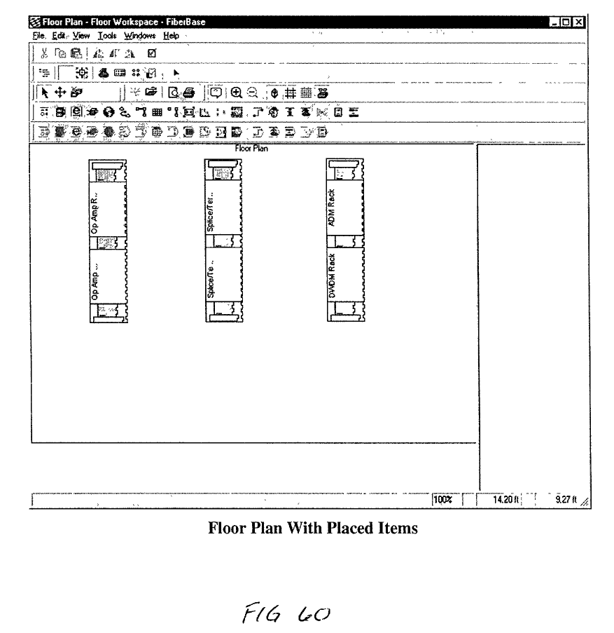

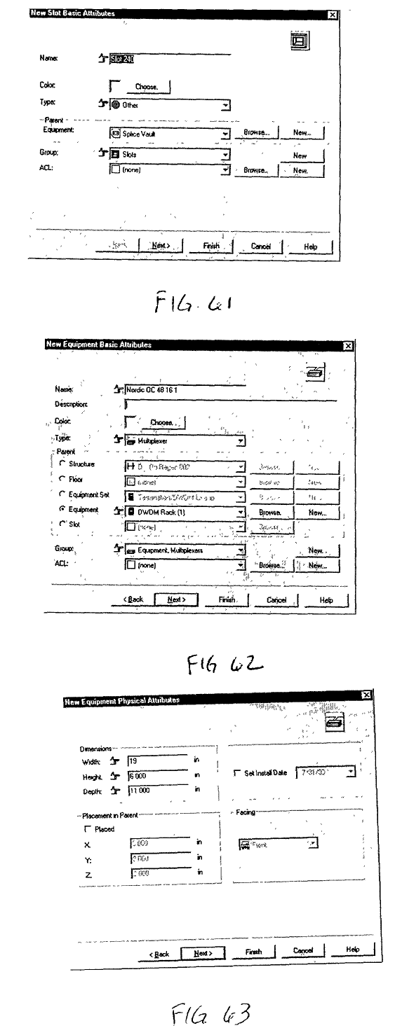

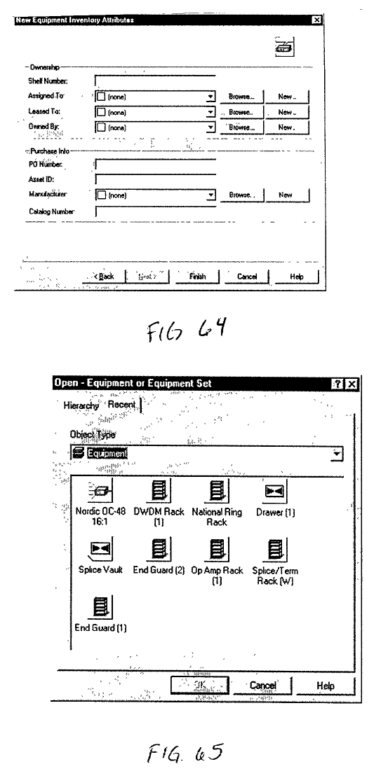

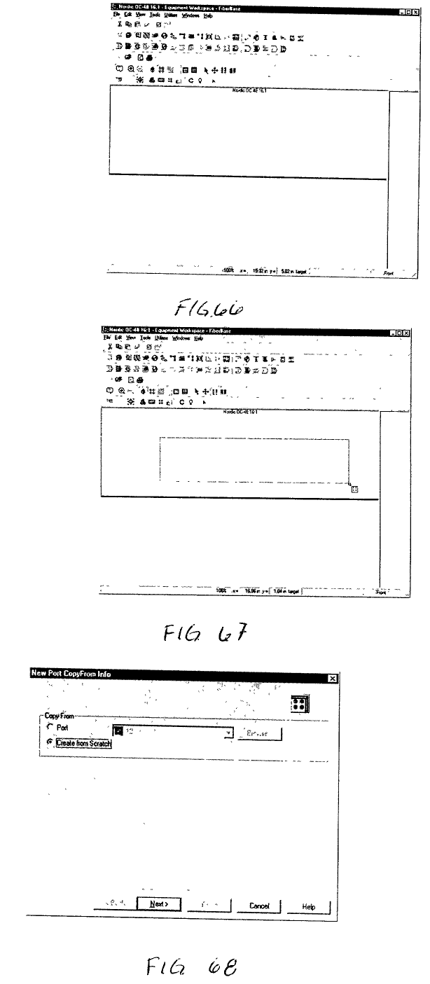

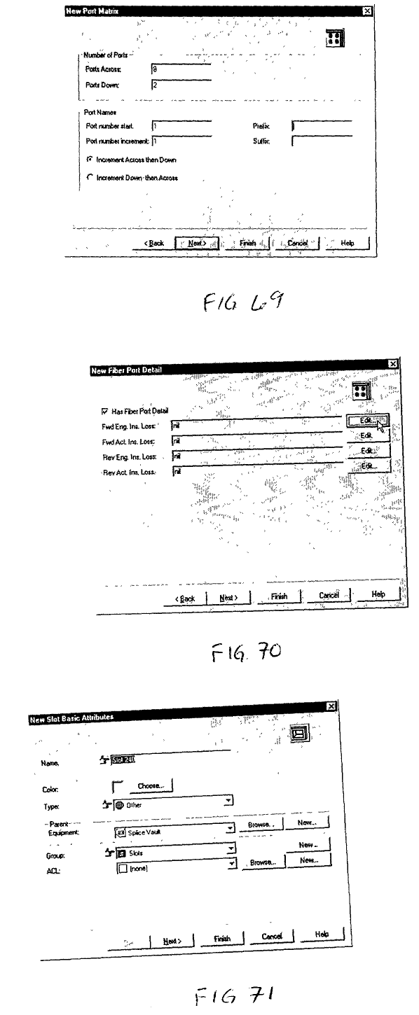

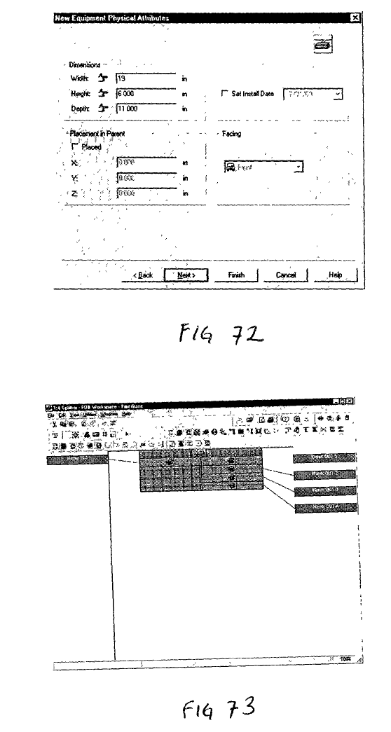

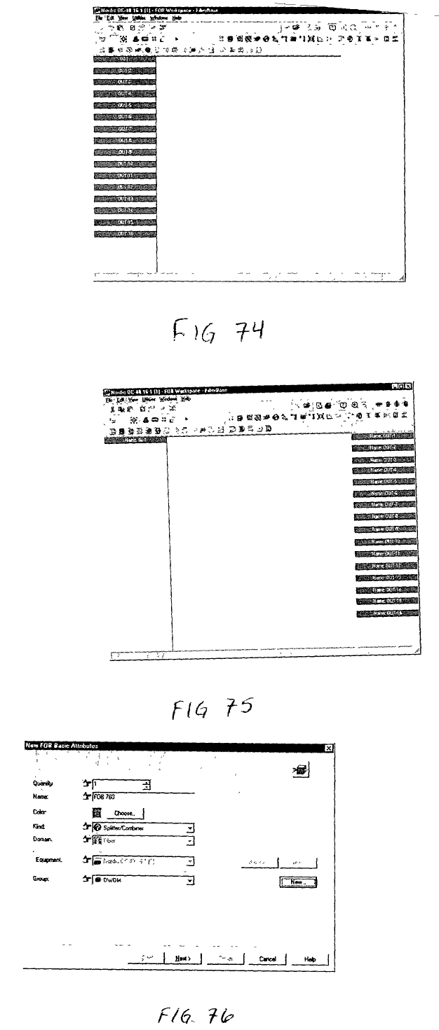

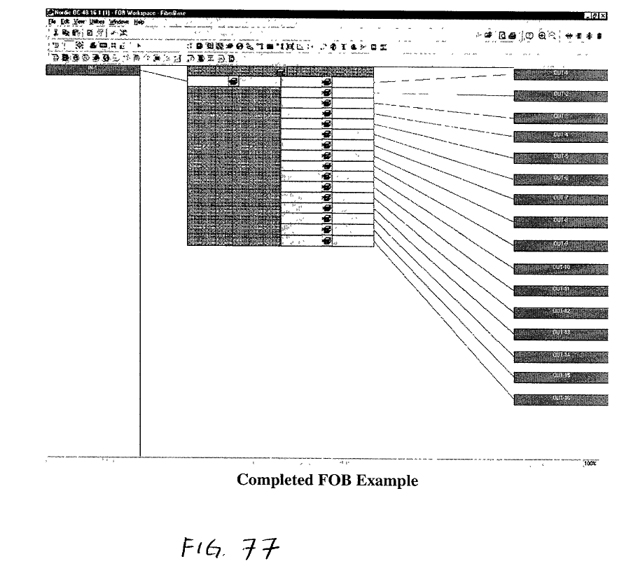

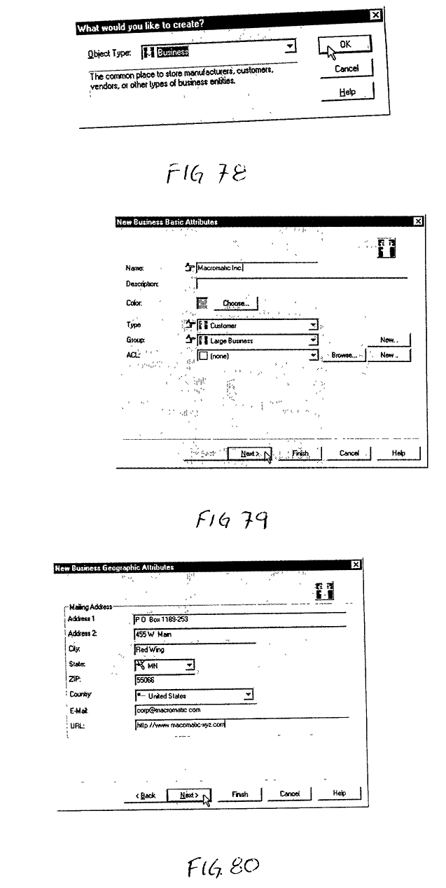

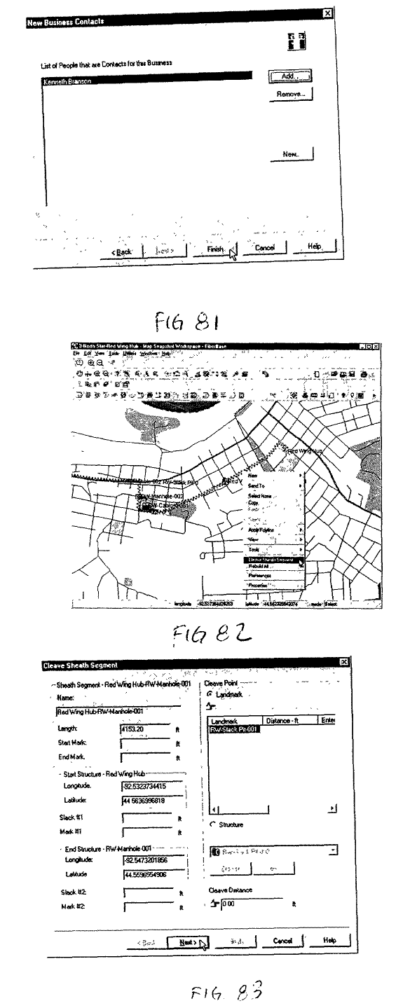

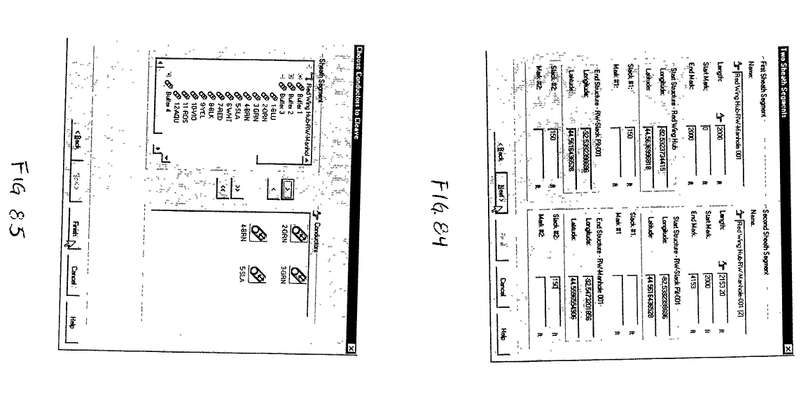

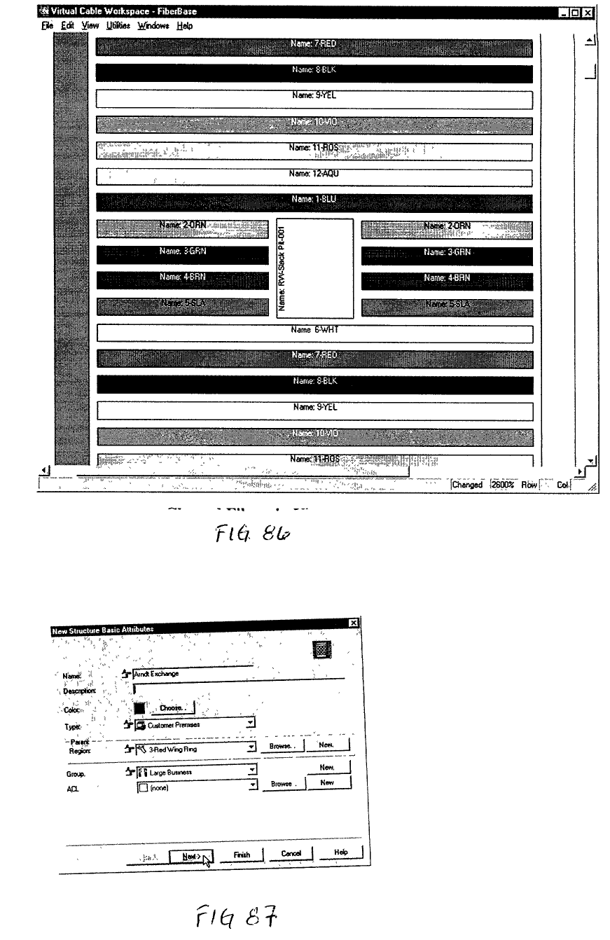

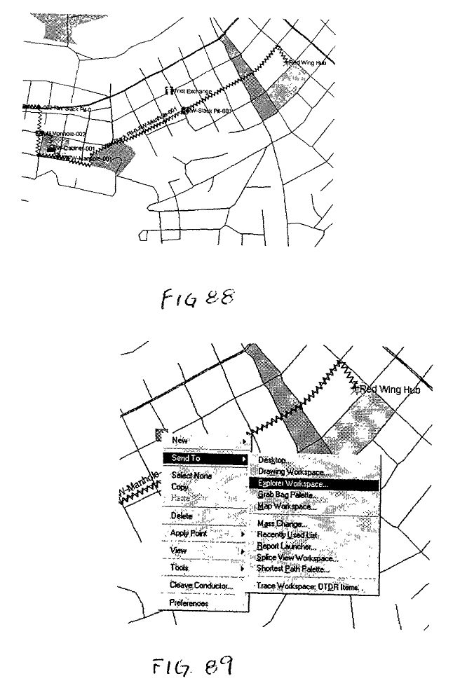

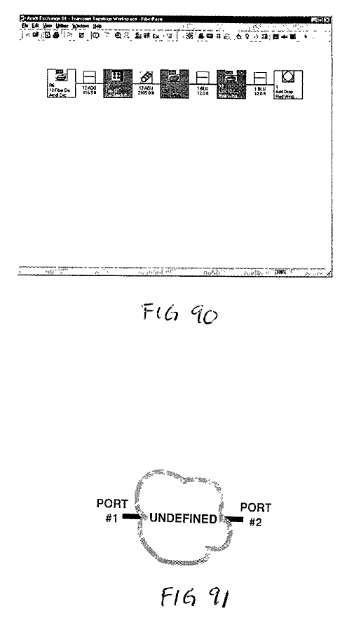

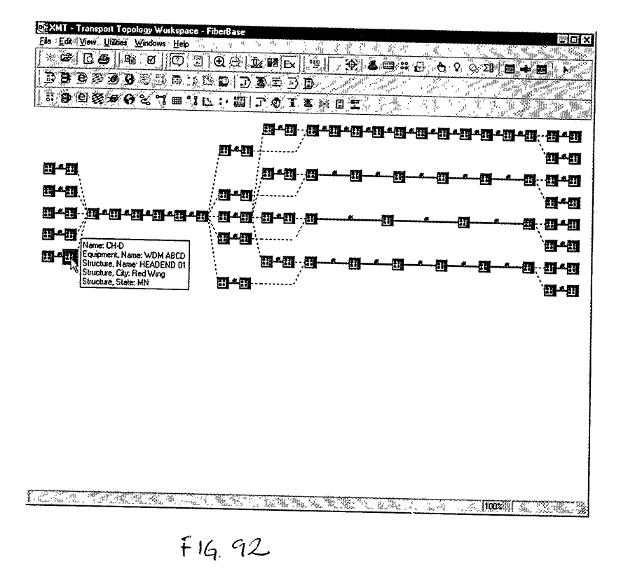

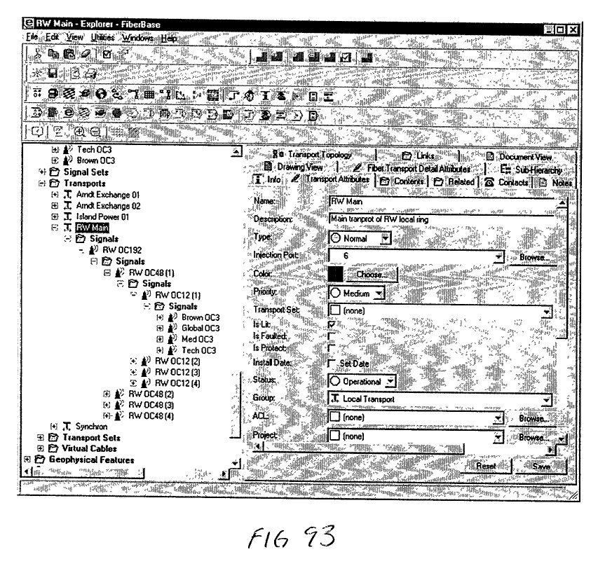

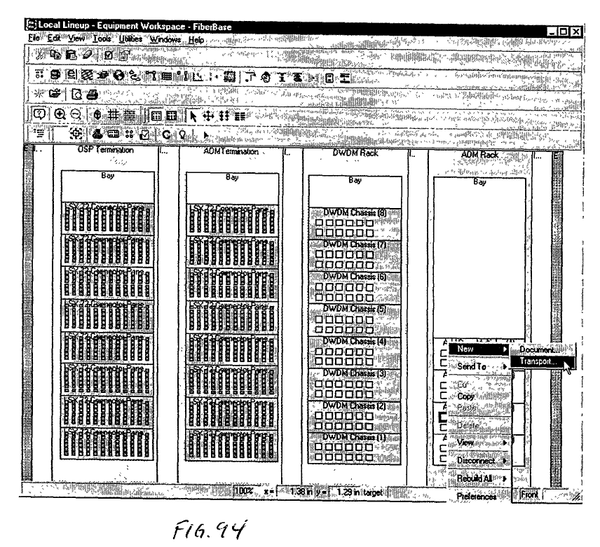

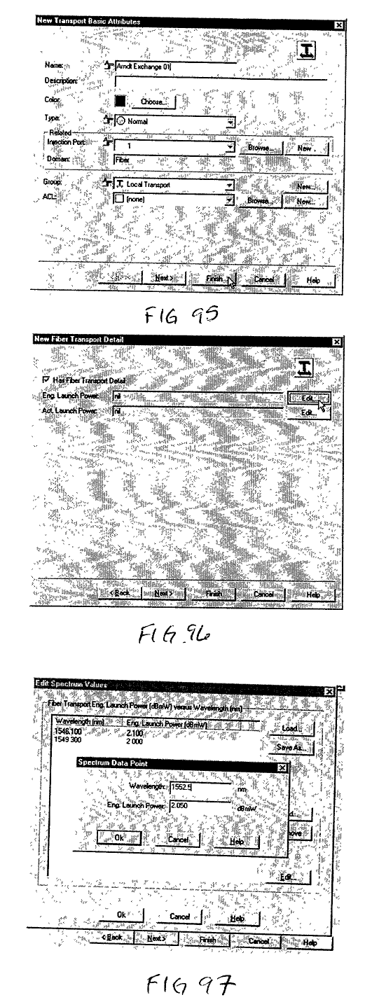

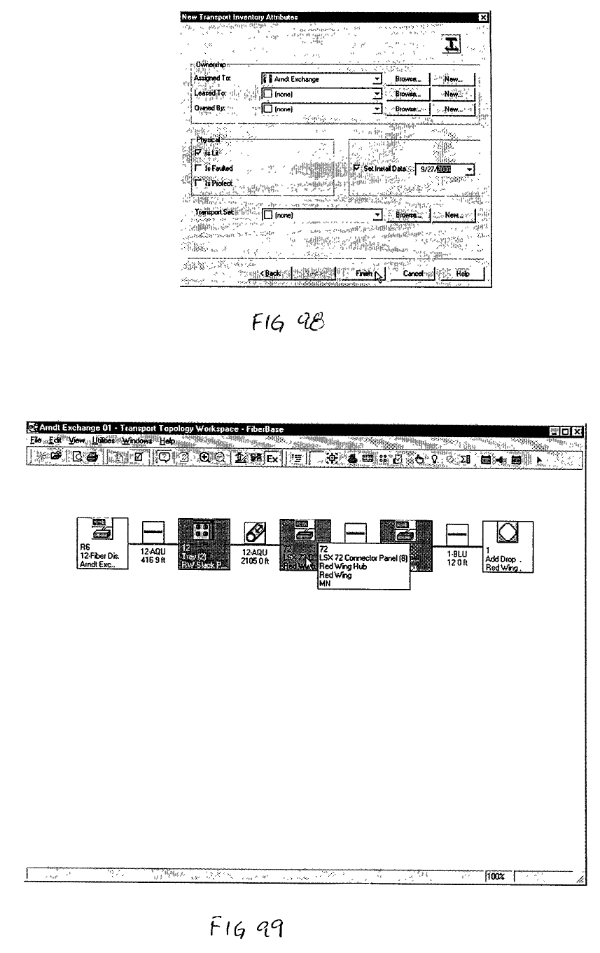

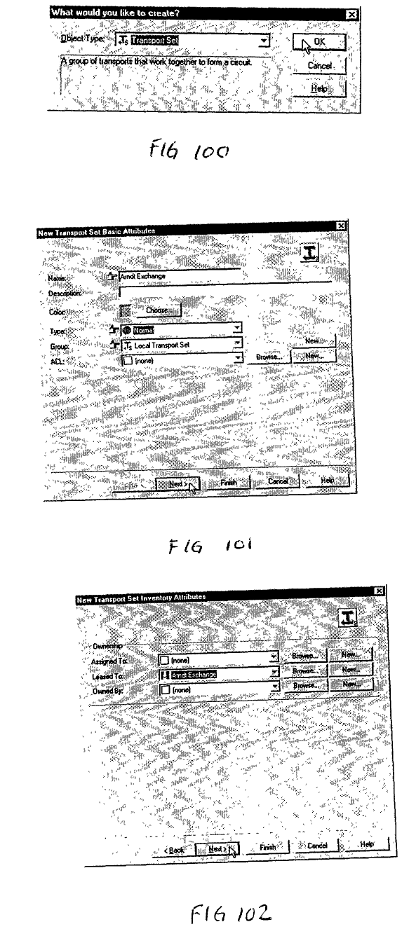

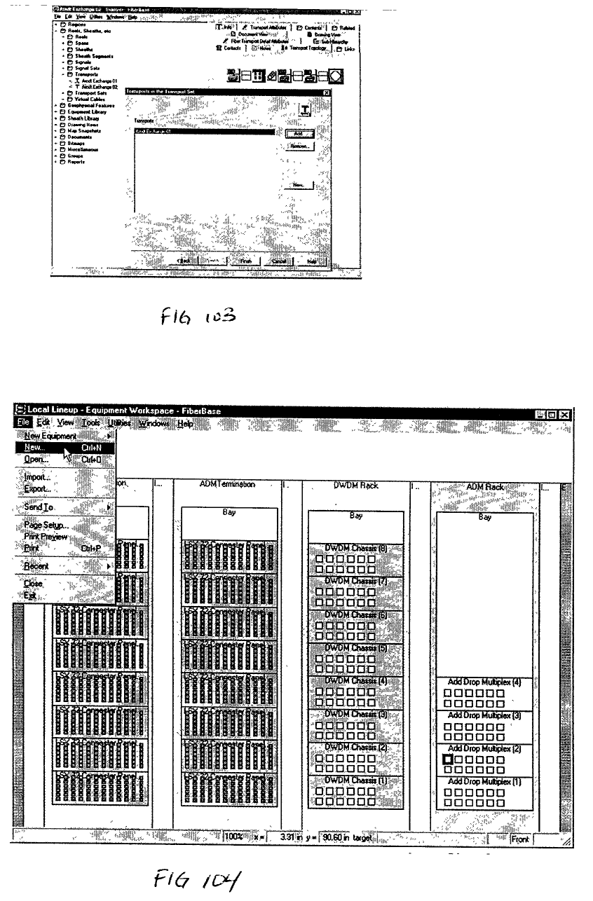

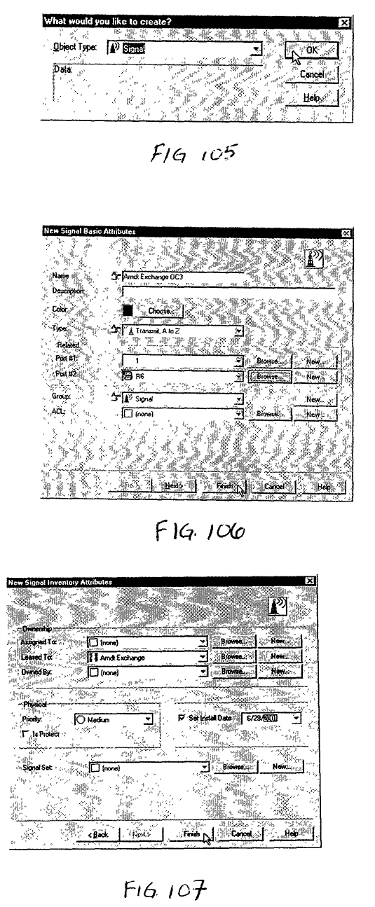

The present invention is directed to a database management system for a broadband network. The system 10 as shown schematically in FIG. 1 includes two main components, a relational database 12 and a graphical user interface 14. The relational database 12 can be located at a user's site or it may be located on a server that can be accessed by one or more users. The relational database allows queries based on any sets of attributes and provides a user with many different ways of obtaining information. For example, one can easily locate all of a certain type of item at a certain type of location. The graphical user interface consists of interactive pictorial windows. The windows represent real-world situations such as maps, floor plans, two-dimensional equipment sets, and cable topologies, for example, one can use these displays to enter and view information. FIG. 2 is an example of an equipment workspace depicting an equipment rack.

The system allows a user to construct a data representation of a real-life network. The network infrastructure model identifies all items in a network, tells where they are located geographically, and tells how they are related to one another through connections, signal transmissions, and so on. The model also serves as a backbone to hold other information about the network, such as business uses, contact people, and network documents.

The network infrastructure model also indicates the main categories of items within the database:

Masters—equipment and sheath entries that is saved for use as templates with other items.

Regions and Structures—the physical components of the network other than sheaths, cables, and their conduits.

Sheaths, Cables, Route Segments, and Routes—the “cabling” of the network: fiber optic sheaths, copper cables, and physical conduits for them.

Connections, Transports, and Signals—the connections and signal uses of the equipment and cabling.

Network Documents—information files attached to network items, for example, spreadsheets and drawings.

The database consists of simply entries for network items, information on secondary items such as documents and maps, and entries defining relationships of items. The system's graphical user interface provides multiple, alternative views of the same or similar information. Various workspaces, as will be described hereinafter, are accessible to the user. These different views allow one to view and enter information using a real-world frame of reference. Maps, floor plans, hierarchical structures, rack diagrams, and equipment front and read depictions are examples of different views. For example, if one wants to view or enter information for an existing region, one can view the region as a geographical map, or alternatively as an explorer hierarchy, as shown in FIGS. 3 and 4 respectively. Beginning with any view of an item, one can easily move to a related view of the same item by using the right click menu Send To function, as seen in FIG. 5. The Send To function opens the requested view with the sent item selected. Thus, as shown in FIG. 5, the 3-Red Wing Ring can be sent to the map workspace where that region will be graphically displayed as in FIG. 3.

Although the present invention is described using the Map Workspace to provide an intuitive starting point for many procedures, one can create any type of item starting almost anywhere in the system. To do this, select File [symbol] New to display the dialog shown in FIG. 6, then select the type of item to be created. Wizards are provided to simplify the creation of a new item using an existing item as a template. Also, an item can be designated as a “master,” causing it to be listed in a separate Masters folder.

The first step in building a database of the network is to create a network map. In this step, the Map Workspace is used to create a network map showing the key components of the network, beginning with three types of components: geographical areas called regions, map-point locations, and physical routes for sheaths called route segments. In creating the network map, the corresponding items in the database will also be created. These items will then be accessible using the system's workspaces and tools. If the network is large, sub-regions may be created within regions to indicate physical levels of organization.

Next, using the map snapshots as starting points, sheaths are put in route segments. In so doing, the sheaths are also created in the database, including their end-to-end physical paths called “routes”. Then, locations are populated with location structures and equipment. In this step, location structures are created and replicated to identify the physical structures at the map-point locations put into place in previous steps. Central offices, OC hubs, and outdoor cabinets are examples of different types of location structures. As part of the location structure, the equipment installed at each location is identified. Structures can be copied and pasted. Sheaths are then connected to equipment. In this step, starting with the map snapshots, one uses an interactive pictorial display to “connect” conductors, fibers or copper to specific ports on specific equipment. Transports and signals are then defined. Using the map snapshots, the physical paths (“transport”) and content of specific signals are defined.

Then business accounts are set up and customers are hooked up. In this step, transports identified in the previous step are used to identify customers. As part of this, one also enters information for “customer premises,” to show any relevant physical structure and equipment in the customer site. Documents are then attached to network items. In this step, support information for the network is entered by attaching “documents” to items. Documents are files such as drawings and spreadsheets created using third-party applications. OTDR test paths are then set up. In this step, portions of routes are designated as Optical Time Domain Reflectometer (OTDR) test paths. Using the Trace Workspace, an access point for each test path is identified and a reference trace is loaded for comparison against test traces. All of these steps will be described in greater detail hereinafter.

Summarized in terms of types, the system's user interface contains four main types:

Desktop

Workspaces

Wizards

Palettes

The desktop as shown in FIG. 7 is the initial window that comes up when the system is started. The desktop contains an icon for each of the workspaces. It also contains any other items such as “map snapshots” that are “sent to” the desktop. The system's workspaces are interactive pictorial views designed to allow the user to view and enter information based on real-world frames of reference. By interacting with a display to enter or edit items, one enters the corresponding information in the database. These are various types of workspaces that will be described below.

A map workspace, as shown in FIG. 8, is used to create a “network map,” thereby creating the same items in the database. Geographical areas called “regions,” structures” where equipment is located, “routes” for fiber optic sheaths and coaxial cables, and such “sheaths” themselves, are all displayed on a map and can be moved on the map to new locations. An explorer workspace, as shown in FIG. 9, is used to view a folder hierarchy of all database items, for selection, copy, paste, etc. When an item is selected, it displays with a set of info tabs as shown.

A floor workspace, as shown in FIG. 10, is used to create, view, and edit floor diagrams showing how equipment sets are located on a floor, from above looking down. Creating an equipment set in the floor diagram creates the equipment set in the database, also. An equipment workspace, as shown in FIG. 11, is used to create, view, or edit a configuration of equipment in an equipment set or structure, thereby entering the same information in the database. This workspace can also be used to move or delete equipment, causing the new equipment configuration to be saved in the database.

A functional object block (FOB) workspace, as shown in FIG. 12, is used to define, view, or edit an FOB defining signal paths between input and output ports within equipment. The signal path is used by the transport function to determine the entire path of a signal form an identified port to the signal's endpoint. A sheath workspace, as shown in FIG. 13, is used to define, view, or edit the inner structure of a sheath (for example, number of buffers and fibers). Preferably, each subunit of the sheath has its own name and color.

A sheath segment topology workspace, as shown in FIG. 14, is used to view one or more segments of a sheath or sheath span as a box and line type topology composed of the segment themselves (lines) and the structures (boxes) at which the segments are terminated on either end. A sheath segment matrix workspace, as shown in FIG. 15, provides an interactive summary of all locations that a sheath passes through. A virtual cable workspace, as shown in FIG. 16, is used to define and name a structure composed of one or more conductors in one or more sheaths. The usual reason for doing this is to identify a group of fibers with a common network function or customer designation. A splice view workspace, as shown in FIG. 17, is used to view and enter information on splices using a pictorial representation of a splice tray. The splice view is used for any type of conductor to conductor connection. A route segment topology workspace, as shown in FIG. 18, is used to view and enter information on the physical routes of sheaths.

A trace view workspace, as shown in FIG. 19, is used to view test results from an Optical Time Domain Reflectometer (OTDR). After displaying a trace graph as shown, one can apply a sheath segment topology to the trace, causing the topology to be displayed (in the workspace area above the trace) and causing topology structures and landmarks to be aligned with the trace based on length from origin.

Wizards may be provided whenever a new item in the system is created. A wizard is a multi-window prompt that guides the user in entering the required information. Various wizards will be described hereinafter.

Palettes are pictorial views like workspaces but generally are simpler in function. A shortest path palette, as shown in FIG. 20, finds the shortest path between two or more selected structures. The path may be either the shortest physical route between the listed locations or the shortest sheath segment path or the shortest route segment path between the identified structures. An information palette, as shown in FIG. 21, is used to view information tabs for a selected item (for example, sub-hierarchy view shown here). The icons in these views can be used to drag and drop items into other workspaces. A connection palette, as shown in FIG. 22, is used to connect, view and enter information on connections of conductors and equipment. Any number of equipment and conductors can be dropped into this workspace and connected individually or using a mass connect function. Mass connect can be used to connect straight through multiple pieces of equipment. A mass change palette, as shown in FIG. 23, is used to change a set of items at the same time. Given a set of items and an attribute name, this function will find the most common value that attribute has among the set of items and allow the attribute to be changed to a new value for all items in the set.

The system's database is a powerful, flexible tool for obtaining information concerning a network's broadband network assets. Starting with the map view one can find and display items based on geographical location. Queries are performed by dragging out a query area with the mouse. In response to the query, all of the system's items in that area are displayed on the map. One can select any of the system's items in a map and send it to another workspace to view or edit details. One can view the location in a number of different ways, including as an Explorer folder structure, or as a card deck of info tabs. One can view the complete database contents as an Explorer hierarchy of information. Using this arrangement, one can view a list of all map snapshots, for example, or a list of all equipment structures or all equipment identified as “masters” for use in templates in creating other equipment. Each region can also be viewed here as a separate, hierarchical structure containing all items within it. One can view network items using, in all cases, a frame of reference suited to the task at hand. For example: If the frame of reference is a physical bay containing equipment, one can view an equipment set as that, rather than a hierarchy as just described. If the frame of reference is a floor plan, one can view the equipment at that floor plan. If the frame of reference is an individual piece of equipment, one can view the equipment front and rear sides and jump from that to information on an individual port. One can select an individual sheath and view a display showing its inner structure. Using the network map or the Explorer, or any display showing a particular sheath, one can send the sheath to the Sheath Workspace to view or change its inner structure.

One can determine the distance between two locations on a map. Simply select the two locations on the map and use the measurement function. One can find the shortest distance or shortest existing physical route between two locations. In a situation where one needs to plan the routing of a sheath, one can merely select the two end locations and query for the shortest route, which will be highlighted on the map. One can select a fiber or port and find where a signal goes that is traveling through it. After the transports and signals have been defined, one can select any connected port through which a transport passed, and find the origin, endpoint, and complete path of the signal. One can view the network as a sheath or transport topology. Any connected matrix of sheaths or transports can be viewed as a topology of boxes and lines providing a simplified view of connectivity between the items. One can perform a relational query to find an item or set of items. Using the FiberBase Finder, one can frame relational queries to find an item or set of items based on any combination of valid attributes.

Changing information is intuitive and straightforward, and can be done in many different frames of reference choosing the one most fitting. For a summary of possible changes, see Table 1 below.

TABLE 1
Changing Items

| Item | Description of Possible Changes |
|---|---|
| Regions | One can rename a region, redraw a region's boundaries, |
| | place a region “under” or “over” another region, and |
| | enter new attributes or edit existing ones. One can also |
| | delete an empty region. |
| Map-Point | One can rename a location or move it (by dragging it |
| Locations | to a location on a map or by changing its longitude and |
| | latitude). One can enter or edit attributes such as |
| | description, name, group, contact people, and so on. One |
| | can delete an empty location. |
| Location | One can add or remove hierarchical levels from a location |
| Structures | structure. One can copy and paste structures to replicate |
| | types (customizing them later). |
| Equipment | One can rename or reorder equipment sets such as lineups |
| Sets | and bays by either editing attributes or by moving items |
| | pictorially. One can enter new attributes or edit. |
| Route | One can move route segments and the routes defined |
| Segments | through them by dragging the route segments on a map. |
| and Routes | One can also reroute or rename a route with sheaths |
| | inside it. |
| Sheaths | One can rename a sheath, redefine its inner structure, or |
| | reroute it. You can edit sheath attributes. |
| Connections | One can disconnect and reconnect conductors (fiber or |
| | copper) individually or using mass connect, mass |
| | disconnect functions. |
| Transports | One can rename a transport or reroute it. |
| Signals | One can rename a signal or redefine signal content. |
| Documents | One can rename or edit any document attached to an |
| | item. You can disconnect it from an item. One can attach |
| | the same document to any number of items. |

Creating a Network Map

Next, the process of creating a “network map” will be described. A network map is an interactive, map-based diagram showing key components of the network. There are three main types of key components, regions (geographical service areas), structures (with network equipment), and routes (lines between structures representing physical routes for sheaths). In drawing these key components on the map, corresponding items are also created in the database.

The first step in creating a network map is gathering source information regarding the real-world network. To do this, all pertinent information about the maps that show how the network components are distributed geographically is gathered.

For a summary of source information to gather, refer to table 2 below.

TABLE 2
Source Information for a Network Map

| Type of Information | Description |
|---|---|
| Standard Maps | Ordinary maps with rough sketches of network |
| | service areas, structure, and physical routes of |
| | cables. |
| Visio or | Drawing of system architecture (fiber rings, fiber |
| Other Drawings | deployment plans, CATV layout, or etc.) |
| Service Areas | Listings of all service area with commonly used |
| Listings | names |
| Structure Listings | Listing of all structures with latitude/longitude |
| | coordinates |
| Diagrams of | Hand-drawn or Autocad drawings or maps of |
| Physical Routes | physical conduits for fiber optic sheaths or coaxial |
| | cables |

Organize all source information hierarchically into levels based on network infrastructure (for example, national, regional, local). Within each level, organize information into three categories: geographical areas, structures, and physical routes for sheaths. Decide on a scheme for creating regions, nested regions, and map snapshots corresponding to the physical organization of your network. For guidelines, refer to Table 3. Decide on a scheme for naming regions, structures, and routes. The names should correspond with real-world names, and also should reflect network function (for example, “2-Red Wing OC-48 Hub”). Decide on a scheme for using color. Each item has its own “normal” color, assigned when created. The system also allows each item to be assigned to a “group” and each group has a color.

TABLE 3
Network Types and Regional Configurations

| Network Description | Regional Configuration | Map Snapshots |
|---|---|---|
| Long-haul fiber network | Create a parent region | Create a parent map |
| distributing signals to local | containing the long-haul | snapshot showing the total |
| rings, each serving a large | components only. Within | distribution area of the |
| area such as a campus or | this parent region, create | network. Then, as one |
| city. The network extends | sub-regions for each local | zooms into each region, |
| into the local ring and may | ring. Within each local ring | create a map snapshot |
| extend further into sub- | region, create a sub-region | showing just that region. |
| rings (for example, OC-48 | for each sub-ring. Create | Continue on down with a |
| to OC-3). | other sub-regions as needed | separate map snapshot for |
| | for special cases like an | each sub-region. |
| | interfaced CATV system. | |
| This network consists of | Create a parent region for | If the network consists of |
| one or more local rings | each local ring. Within | multiple local rings, first |
| (such as described above), | each of these regions, create | create a map snapshot |
| with a vendor in some cases | one or more sub-regions, as | showing all the parent |
| providing the link between | needed, for sub-rings and | regions. Next create a map |
| them. This network may | interfaced systems. | snapshot for each parent |
| also extend into the local | | region, then zoom in and |
| ring to sub-rings and other | | create map snapshots for |
| interfaced systems. | | each local ring. |
| This network consists of a | Create a parent region for | Create a map snapshot |
| single fiber ring with no | the entire local ring. Create | corresponding |
| sub-rings. This network | sub-regions corresponding | geographically with the |
| uses a vendor for receipt | to the physical organization, | distribution area of the |
| and transport of data | if any, within the local ring. | single ring. Create lower |
| beyond its own ring. | | level map snapshots for any |
| | | lower-level mapped areas |
| | | such as service areas. |
| This network is a legacy | Create a parent region for | Create a map snapshot of |
| telephone system providing | the entire telephone system | the entire distribution area. |
| advanced two-way services | area. Within this region, | Then, as you zoom in to add |
| (for example, using DSL). | create a sub-region for each | details, create map |
| | other physically separate | snapshots of each area of |
| | component of the network. | map detail. |
| This network is a CATV | Create a parent region for | Create a map snapshot of |
| system with advanced two- | the entire distribution area. | the entire distribution area. |
| way services (for example, | Within this, create sub- | Then, as you zoom in to add |
| using RF mixing). | regions for the headed and | details, create map |
| | for each physically separate | snapshots of each area of |
| | component of the network. | map detail. |

The system uses the Map Info application to provide map displays. Maps in the Map Workspace are composed of “layers” (for example, “streets”). Each higher-level layer overwrites any layers below it. The layers can be moved up and down to show the desired detail. Any map view can be named and saved as a “map snapshot” for later use when needed. The Map Workspace has “balloon info” that can be turned on and off. If balloons are on, when an item is pointed out, a balloon appears listing attributes as determined by item type and the Edit [symbol] Preferences tabs. All geographical positioning on the map is stored in the database as sets of one or more longitude-latitude coordinates.

For a summary of common tasks done with maps, refer to Table 4 below.

TABLE 4
Source Information for a Network Map

| To Do This | Do This |
|---|---|
| View or | Select Maps [symbol] View Layers. Use the Up and Down |
| rearrange | buttons to move layers up or down as needed. Labels can be |
| layers | turned on or off for a layer or a layer can be made invisible. |
| Open a new | Select Map [symbol] Open Map and browse through files to |
| map set | find and open the desired map set. |
| Change skew | Select Map [symbol] Snapshot Properties and use the Rotation |
| of longitude | and Projection functions to adjust the longitude-latitude |
| and latitude | skew. |
| lines | |
| Create a map | Select Map [symbol] Save Snapshot. Name and save snapshot. |
| snapshot | |
| Open a map | Select Map [symbol] Open Snapshot. Open the Map Snapshots |
| snapshot | folder and select the map snapshot to display. |
| Create a | Click on the new region icon (see 16 in FIG. 8) then draw a |
| region | polygon using mouse clicks. Upon returning to the point of |
| | origin, double-check the mouse; use the wizard to |
| | enter name, etc. |
| Create a | Click on the new map point structure icon (see 18 in FIG. |
| map-point | 8) then click on the map at the desired map point. Use the |
| structure | wizard to enter name, etc. |
| Create a | Click on the new route icon (see 20 in FIG. 8) then click on |
| route | a structure at either rend of the desired route. Use the |
| | wizard to enter name, etc. |

Preferably, the process is started at the highest level of the network infrastructure down to areas of detail. This involves creating a top-level region and then as many nested regions as needed to represent the real-world network. Each completed region will contain three main components: regions, structures, and routes. After gathering and organizing source information as previously described, the network map can be created.

After gathering and organizing source information as previously described, the network map can be created. As items are created on the map, the same items are created in the database. Preferably, a wizard will assist a user to create a new item. The top-level region should contain the top-level infrastructure of the network. If necessary, multiple top-level regions, either adjoining one another or in distributed structures may be created. If so, each top-level region should have lower-level regions as will be described. To create the top-level region click on the Map Workspace icon in the system's desktop to open the Map Workspace. The workspace comes up in the default map snapshot as shown in FIG. 24.

Using the zoom in, zoom out, and pan functions, adjust the map scale and framed area to show the distribution area of the entire network. If the appearance of the map is to be altered to bring out relevant details such as highways, select Map [symbol] View Layers and use the Up and Down buttons to move layers up or down as needed. Once the basic view to start with, select Map [symbol] Save As to create a map snapshot. Use the dialog to name and save the map snapshot.

A region is created as follows. If the parent region being created has the same boundaries as a map object, such as a state, right click on the map object and select “New Region” from the right click menu, as shown in FIG. 25. If there isn't a convenient map object to base the region shape on, click on the new region icon, then click on the map on any point of its boundary. Use successive clicks to mark other points on the boundary. When back to the point of origin, double-check to complete the boundary. A new region wizard is shown in FIG. 26 displays. In the new region wizard, key in the region name. Enter a name matching the map snapshot name (for example, “1-Top Level Region,” using the same numeric prefix that you used for the map snapshot). For Type, select “Other” for the time being or click on the Help button for instructions on how to create a type based on your needs. For Group, select New and use the new group wizard to create a group called “Top-Level Region,” or some similar name as seen in FIG. 27. Key in any other values as desired, then click on Finished to enter the new region in the database. FIG. 28 is an example of a finished region. Select Map [symbol] Save to save the snapshot with the new region.

Within the parent region, create map-point structures for all points of contact from the top-level network infrastructure to the next lower level. To create the structures, click on the new structure structure button (see 18 in FIG. 8), then click on the map at the desired map point of the first new structure. In the new structure wizard, as seen in FIG. 29, key in a structure name. For Group, click on New and use the new group wizard to create a group to be used for all points of contact of this type in the network. Click on Finish to complete the group and return to the new structure wizard. When done with the structure entries, click on Finish to enter the new structure in the database. FIG. 30 shows the new structure “Red Wing Hub” added to the map.

The remaining top-level structures are created in the same manner. Assign all structures of the same type to the same group, for example, OC-48 hub.

Next, a straight line route is created between each set of two structures where a route exists. Click on the icon for either structure, causing the icon to be highlighted. Press down the CTRL key and click on the icon for the second structure. Both icons will now be highlighted. Select Maps [symbol] New, as shown in FIG. 31. A “create what” prompt, as shown in FIG. 32, will appear and in response select Route. A new route wizard, as seen in FIG. 33, will appear. In response key in a route name conforming to the overall network nomenclature scheme. For Group, click on New and use the new group wizard to create a new group for long-haul trunks. When done entering route information, click on Finished to enter the new route in the database. FIG. 34 illustrates the created route. Continue creating routes until all are drawn, as shown in example in FIG. 35.

To see the new region in the Explorer view, click on the explorer icon in the desktop (see 30 in FIG. 7) and the Explorer screen as shown in FIG. 36 displays. A plurality of folders appear at the right of the display that can be selected to display various information about a selected item.

After creating a parent region, the next step in creating the network map is to “draw” on the map the next lower level of network infrastructure. This will create the same items in the database. Each second level region should contain a particular point of contact between the top-level and second-level network and the associated second-level infrastructure, for example, the add-drop mux for a state-wide OC ring, the ring itself, and points of contact to lower level network structures. For each second-level region, one should also create a map snapshot using nomenclature that indicates region level, for example, “2-North Star.” The result will be a hierarchical list of map snapshots.

In the system's Desktop, double click on the icon for your top-level map snapshot. The workspace comes up showing the top-level network infrastructure of map-point structures and routes, as shown in FIG. 37. Using the zoom in, zoom out and pan functions, adjust the map scale and framed area to focus on one point of contact showing the entire lower-level structure originating at that point of contact, as seen in FIG. 38. If the appearance of the map needs to be altered to bring out relevant details such as highways, select Map [symbol] View Layers and use the Up and Down buttons to move layers up or down as needed. When the desired view is obtained, select Ma [symbol] Save to create and save a map snapshot.

Define the region boundary by either selecting a geographical object or by drawing the boundary with the mouse as previously described. In the new region wizard, key in a name matching the map snapshot name, for example, “2-North Star”. In the Parent Region box, select the top-level region. For “Group,” select New and use the new group wizard to create a group called “Second Level Region.” Key in any other values as desired, then click on Finished in the new region wizard to enter the new region in the database. Select Map [symbol] Save to save the map snapshot showing the region. FIG. 39 shows an example of a map snapshot for a new second-level region. Within the new second-level region, create map-point structures for all points of contact from the second-level network infrastructure to the next lower level (for example, OC-48 to OC-3). To create the map-point structures, click on the new structure structure button (see 18 in FIG. 8). Click on the map at the desired map point of the first new second-level structure. In the new structure wizard, key in the structure name consistent with the overall network nomenclature scheme. For Parent Region, select your second-level region just created. For Group, click on New and create a new group for your second-level network points of contact, for example, OC-3 Hub as shown in FIG. 40. When done, click on Finished to enter the new structure in the database. Continue creating map-point structures for all structures serving as points of contact from the second-level network infrastructure to the next lower level of the network. When done with all structures in the region, select Map [symbol] Save to save the map snapshot.

Now routes can be drawn between new structures. Click first on the structure that is the point of contact between the top- and second-level network infrastructure. Hold down the CTRL key and click on a lower-level structure that connects directly to the first structure. Select Map [symbol] New and in the “create what” dialog, select Route, as shown in FIG. 41. In the new route wizard, key in a route name conforming to the overall network nomenclature scheme. For Group, click on New and create a new group denoting the infrastructural role of this route (for example, OC-3 ring). Select a route color different from the long-haul route color previously created. When done, click on Finished to enter the new route in the database. Continue creating other routes in the same manner until the second-level infrastructure within the region being mapped is completed, as shown in FIG. 42. Select Map [symbol] Save As to save the map snapshot.

After creating the second-level regions, any third- or lower-level regions nested within the second-level regions can be created. The procedure is similar to the process already described. In drawing the lower-level regions on the map, the same items are created in the database. A data structure representing all service areas, equipment structures, and routes in the total network is created.

For each lower-level region, a map snapshot using nomenclature that indicates region-level (for example, “3-North Star-Red Wing” for a map showing an OC-3 ring within the North Star second-level region and serving the city of Red Wing). The map, in this case, corresponding with the Red Wing third-level region, would shown the complete distribution of the third-level region.

After all structures are created, draw routes between the structures corresponding to the network infrastructure need to be drawn. The exact physical path of the routes is of no concern at this point. The object is to simply denote connectivity between structures. Click on the select icon (see 32 in FIG. 8) to place the workspace in select mode. Click on the first structure. Press down the CTRL key and click on the second structure. Using the new route wizard, key in a route name corresponding with the overall network nomenclature. For Group, create a group for the network routes at this level. FIG. 43 shows an example of new routes in the Map Workspace.

If the network contains nested infrastructures such as a CATV system receiving advanced two way services from a fiber ring, it may be desirable to make the special case infrastructure a separate region. A map snapshot can be created showing just the detail for the special case region. Select Map [symbol] Save As and save the map snapshot using a name consistent with the overall network nomenclature for naming map snapshots. Click on the new region button to put the workspace in new region mode, then click with the mouse to draw the region boundary. Using the new region wizard, key in a region name corresponding with the overall nomenclature scheme, for example, “4-NS-Red Wing-CATV”. For Group, create a new group for the type of network, for example, CATV. When done, click on Finished to enter the new region in the database. Create structures for this region as in previous regions already created. Assign structure names consistent with the overall network nomenclature. For Group, create a new group for the special type of infrastructure being entered, for example, CATV system. After all structures are created, draw routes between the structures corresponding to the network infrastructure. Use the same method to draw routes as in the higher regions. Assign the routes to the same group just created. When done with the entire region map, select Map [symbol] Save to save the map snapshot showing all network components.

To display information for any item on a map, select the item and press F2 to display the Info Palette, as shown in FIG. 44. To change attribute values for the item, click on the item attributes tab in the Info Palette, enter any desired new values, and click on Save.

To view a bubble containing an information display for whatever map object the mouse is pointing at, click on the bubble button (see 34 in FIG. 8), then point at any map object.

A hierarchical network map containing geographical regions, map-point locations, and straight-line routes between locations has been created. Next, map details including splice points, actual paths of physical routes, and sheaths can be added to a lower-level region, such as Level 3. Splice points are just another type of location structure, created with a mouse click and wizards.

Actual paths of physical routes are created by drawing route segments between splice points using the mouse. After all the route segments are completed, one can drop the original straight-line route into the new, more exact route. Sheaths are any type of fiber optic sheath or copper cable. Creating them on the map is as simple as creating location structures. Just put the Map Workspace into the correct mode, click on the end points where the new sheath is to be entered, and the new sheath wizard assists in entering the required details.

For route segments and sheaths, gather all pertinent information showing physical routes of sheaths and listing sheaths by location and type. For a summary, see Table 5, below.

TABLE 5
Source Information for Route Segments and Sheaths

| Type of | |
|---|---|
| Information | Description |
| Standard | Ordinary maps with drawn lines representing actual |
| Maps | physical routes of sheaths. |
| Route | Drawings showing actual physical routes of sheaths in |
| Drawings | reference to other landmarks such as waterways, highways, |
| | streets, or railroads. |
| Sheath | Lists of all sheaths at a particular location or in a particular |
| Lists | geographic area. To be useful, the list must indicate where |
| | the sheath terminates on either side. The list must also |
| | indicate the cable type and inner structure of each sheath. |

Organize source information into map areas defined by the regional boundaries for lower-level regions. Take special note of route segments that follow along geographic objects such as a highway or street. Pressing down the Shift key while drawing a route with the mouse causes the route to follow along the line of the map object. Decide on a scheme for naming sheaths. The names should correspond with real-world names, but also should reflect network function. Note that, when creating a sheath from scratch, it can be designated as a “master.” A master is simply an entry that is kept in a separate folder where it can be found easily for use as a template in creating a new sheath. The system allows one to copy an existing sheath. Decide on a scheme for using color. Each route segment and sheath has its own color, assigned in the wizard when the item is created. Also, each item is assigned to a “group,” and each group also has a color designation. Color display by group can be used to visually separate different categories of items such as manholes vs. above ground enclosures vs. splice pits.

Refining a straight-line long-haul route involves two main tasks. The straight-line original route is replaced with an actual path route conforming to where the real-world lies on a map. Structures along the route representing real-world network infrastructure sites such as splice points are created. Assuming a typical optical ring topology with DWDM technology, four main kinds of network infrastructure sites are created. Optical Regeneration (OP Regen) Sites (typically huts, located about every 300-500 miles); Optical Amplification (OP Amp) Sites (typically huts, located about every 50 miles between op regens), Splice Points (typically handholes located every five or six miles, on either end of each sheath, except where the sheath ends at an op regen or op amp) and Slack Pits (usually handholes, located at several points along each sheath to provide a place for storing slack).

After creating each structure, the actual path “route segment” between that structure and the preceding structure is drawn.

In the Explorer Workspace, select the top level region for the network, then select the Contents tab. In the Contents tab, click on the hub for the route to be refined, then CTRL click on the hub on the other end and on the route itself. Right-click on any of the selected items and select Send to [symbol] Map Workspace from the right-click menu, as shown in FIG. 45. In the Map Workspace, as shown in FIG. 46, select the long-haul route, then press the “+” key in the numeric keypad one or more times as needed to zoom in on the route. Select either hub on the map and press the “+” key on the numeric keypad again, as many times as needed, to zoom in on the hub. Starting at the hub, move along the actual-path route to locate the first infrastructure site such as a slack pit. If additional detail such as street names is needed, select File [symbol] Open Map and browse to and open a map layer containing the detail needed. Then select View [symbol] Layers and move the layers up and down as needed to show the detail needed to position your structures.

Click on the add structure button, then on the map location of the structure being added. In the New Structure Wizard, key in the structure name and identify the parent region as the region containing your straight-line long-haul route. Enter any other information desired, then click on Finish. Click on the add route segment button, then with the mouse pointer draw the actual path of the route between the two structures. To do this, click on the first structure, then click on any point along the path where it changes direction. At the second structure, double-click to finish the route segment. In the New Route Segment Wizard, shown in FIG. 47, identify the parent region as the region containing your straight-line long-haul route. Key in any desired information. When done, click on Finish to enter the new route segment in the database.

The new route segment displays, as shown in FIG. 48, by a red line. The original straight-line route is the straight blue line crossing above the new route segment.

On the map, continue along the actual path of the long-haul route to the next network infrastructure site. Add a new structure at that location, then add a route segment and draw it between the previous structure and the new one. Two route segments are made, as shown in FIG. 49.

The process of refining metro routes is similar to that of long-haul routes, except that a metro route typically includes some additional types of structures such as outdoor enclosures. Also, the routes are typically shorter. Continue creating structures and route segments until all of the old straight-line routes with new structures and new route segments are replaced.

Once all actual path routes are created, sheaths can be created and put in the routes. By doing this, the same sheaths are created in the database and indicate their real-life geographical routes.

Display a map showing the structures and route segments into which a sheath is to be placed. Click on the new sheath button (see 36 in FIG. 8) to put the workspace into the correct mode for adding a new sheath. Click on the structure on one end of the sheath, drag out the black dotted line to the second structure, then double-click on the second structure. The new sheath wizard displays with a first page that allows you to choose between copying properties from an existing master, creating a new master, or creating a sheath from scratch.

Up until now entering “structures” on the network map was just names with longitude and latitude attributes. Structural details to indicate what physically exists within each structure can now be added.

Adding Structural Details

Structures are based on nested levels of physical containment. For example, a typical network “building” contains, in descending order, floors, equipment sets, equipment, and, in some cases, smaller components such as splice drawers and splice trays. A similar nesting scheme defining any type of network structure such as a hut, outdoor cabinet, manhole, or pole can be created. After creating one of each structure, they can be copied and pasted to replicate them and then edit them to individualize as needed.

As source information for structure details, gather all pertinent information regarding real-world physical structures where network equipment is located. For a summary, see Table 6 below.

TABLE 6
Source Information for Structural Details

| Type of | |
|---|---|
| Information | Description |
| Floor | Two-dimensional, top-down drawings showing spatial |
| Plans | arrangement of equipment sets such as lineups and bays. |
| Lineup | Two-dimensional, front and rear drawings showing spatial |
| and Bay | arrangement of bays within each lineup, equipment within |
| Drawing | each bay. |
| Equipment | Lists of equipment within each structure. |
| lists | |
| Equipment | Dimensions, port locations, and specifications for each |
| Details | unique piece of equipment. (Many of these details are |
| | available within the equipment masters provided with |
| | the software.) |
| Signal Path | Diagrams depicting the signal path between input and |
| Diagrams | output ports for signal-routing equipment such as splitters. |
| | (These are only needed for equipment that you will create |
| | from scratch.) |

Sort out source information into folders or stacks based on structure (one per structure). For each structure, a list of equipment at that structure and drawings showing the spatial placement of that equipment should be provided. Compare structures to one another and consider which structures can be used as templates for other structures (for example, a number of manhole structures containing the same type of splice case may be required). Within the list of equipment that will be made from scratch, identify any equipment such as splitters or combiners that have other than straight-through signal paths. Creation of this equipment is more complex since for each basic type you will need to create a “functional object block” to indicate the paths from input to output ports within that equipment, which will be described in greater detail hereinafter.

Structures are most often encountered in the Explorer Workspace where they appear as Windows Explorer type folder-and-file hierarchies representing descending levels of physical containment. A structure can also be thought of as a sub-hierarchy within the overall “Regions” hierarchy since structures represent the lower level physical components of each region. All structures have, as their top level item, a structure name indicating the structure itself. In most cases, the structure name is associated with a specific longitude and latitude coordinate that can be located on the map, but a structure can be created with no map coordinates. Just as a region may contain any number of nested regions within it, a structure may contain as many nested levels as are necessary to indicate its descending levels of physical containment. A structure also contains folders for other items associated with the structure such as routes, route segments, sheaths, and sheath segments. Shown below is an example.

To identify the various layers of a structure, the system uses building blocks identified as “floors,” “equipment sets,” “equipment,” “slots,” “bays,” and “ports.

Table 7 describes each of the structure building blocks and indicates some common sense restrictions on what can contain what (indicated as “possible parents”).

TABLE 7
Names of Structure Building Block Folders

| Folder Item | Description | Possible Parents |
|---|---|---|
| Floor | Top-view drawing spatial | Structure |
| | placement of equipment on | |
| | floor | |
| Equipment | Enclosure, lineup, rack, or | Structure or floor |
| Set | etc., containing multiple | |
| | equipment | |
| Equipment | Any functional network | Structure, floor, equipment |
| | component | set, equipment, or slot |
| Slot | Place where smaller | Equipment |
| | equipment may be placed | |
| | inside of larger | |
| Port | Place of connection | Structure/equipment (both) |
| | between equipment and | |
| | conductor | |

Creating a structure can all be done from the Explorer Workspace. Just right-click on any item to add something below, select File [symbol] New, and select the type of item to be added. On entry the new item will appear in the structure hierarchy at the appropriate level. In most cases, however, copy and paste functions will be used to replicate pieces of the explorer hierarchy where needed. For example, after creating a standard bay with connector modules, you can copy that whole structure anywhere in your network.

After the source information has been gathered and organized, the next step in entering structural detail is to create one instance of each basic type of structure in the network, beginning with the simplest structure and then progressively dealing with more complicated structures. A particular example will be given for structures common in an optical ring topology, although the present invention is not so limited.

An aerial splice can be represented in the Explorer Workspace by a hierarchy such as shown in FIG. 50. The slot level provides x, y dimensions that allow the levels below the slot to be displayed pictorially in the Equipment Workspace.

In the Explorer Workspace, click down through the Regions hierarchy to display the structure name for which you want to add structural detail. Right-click on the structure name and select New [symbol] Equipment to indicate that you want to add a level for the aerial splice enclosure. The New Equipment Wizard displays as shown in FIG. 51. The wizard provides three choices for creating equipment: creating it from a master, from existing equipment, or from scratch. To determine whether a master is available to use, click on Copy from Master and look through the pulldown picklist that will appear. If a master is available, select it and click on the Next button twice to look at the next two windows. When done, click on Finish. If a master is not available, click on Copy from Equipment and browse within the Explorer to find similar equipment to copy from, then change values as desired and click on Finish. If there is no similar equipment available to use as a template, create equipment from scratch, which will be described in detail hereinafter. After adding the equipment, click down through the equipment hierarchy in the Explorer to look at the levels below it. If a master was used, the master may have brought it in lower levels including a “slot,” if present in the master, and splice trays within the slot. If a slot is not present in your structure hierarchy and you want to have one, create the slot from scratch.

If one or more splice trays (per your real equipment) is not present in the hierarchy (not brought in with the master), position the cursor on the slot name in the Explorer Workspace (or parent item name, if no slot is present) and select New [symbol] Equipment from the right-click menu to display the New Equipment Wizard again to add a splice tray. In the New Equipment Wizard, proceed as you did to add the splice enclosure. Use a master if possible. If a master is not available, use similar equipment as a template or create the splice tray from scratch. When done, click on Finish.

If the equipment has multiple splice trays, right-click on the new splice tray name in the Explorer Workspace and select Copy from the right-click menu, then right-click on the tray enclosure name and select Paste to paste a second splice tray into the slot. Use the Rename item function to rename the copied item. After adding splice trays, if any, right-click on the upper-level equipment name, Coyote Runt in the example, and select Send to [symbol] Equipment Workspace to display a pictorial depiction of the equipment in the Equipment Workspace as shown below. Note that any splice trays added for this equipment are present as icons in the right area of the workspace. Using the mouse, “drag and drop” any unplaced splice trays splice into the slot in the order desired. If after dropping a tray into place, you decide to move it, you can do so by first selecting Tools [symbol] Move and then selecting the splice tray to drag it where you want it.

View the equipment front and back using the View menu Front and Back selections. Note that the front and back views shown in FIGS. 53 and 54 respectively both show the same ports since the ports (being splice representations) were presumably identified as “pass-through.”

The next structure type in degree of complexity is an “outdoor enclosure” such as a splicing or cross-connect cabinet. Typically such enclosures contain an inner rack on which equipment is mounted. Also, in some cases, the enclosure is mounted on an underground sleeve containing a splice enclosure.

As for the other type of structures already completed, build a hierarchy from the top down using the right-click menu. Use masters or existing equipment if available. If not, create equipment from scratch.

Select the cabinet-level item in the Explorer Workspace and select Send to [symbol] Equipment Workspace from the right-click menu to view the equipment and any unplaced items into the equipment slot to indicate spatial arrangement in the real-world equipment. FIG. 55 shows a cabinet in the equipment workspace. Create one instance of each kind of cabinet in your network for later use in replicating your basic structures throughout the network infrastructure model.

The next structure type in degree of complexity are huts with optical amplifiers or optical regenerators. Hut represent a further level of physical organization since they usually contain lineups and racks. Lineups (and other physical groupings of equipment) are represented by “equipment sets. Equipment sets have x, y and z dimensions on which equipment can be arranged spatially. In an equipment set, items must be side by side. They cannot overlap in an x direction. Racks or bays are equipment with slots into which equipment is fitted pictorially. Equipment masters provided with the software already have the slots there. If creating a rack or bay from scratch, the slot must be added. To enter structural detail for a hut structure organize the components of the hut into a hierarchy such as shown in the example, with an equipment set for each lineup in the hut. The basic levels will be:

Lineup (Equipment Set)

Rack (Equipment)

Rack Equipment Area (Slot)

Panels (Equipment)

Splice or Plug-in Area (Slot)

Splice Tray, or etc. (Equipment)

Build the entire structure in the Explorer Workspace, using masters, if possible, of each type of equipment. Use copy and paste to replicate any items that appear in the structure multiple times. After building the entire structure in the Explorer (consisting of one or multiple equipment sets) select a first equipment set and send it to the Equipment Workspace. The equipment set will display, as shown in FIG. 56, with all components of the set in the unplaced equipment area on the side of the workspace.

Beginning with the leftmost rack component (in this case, an end guard), drag the rack components one by one from the unplaced area to their correct pictorial position per the real-world lineup, as seen in FIG. 57. Click on any remaining unplaced item and notice that this causes that item's parent rack (per the Explorer hierarchy) to be selected in the lineup view. Drag and drop the remaining unplaced items into their correct pictorial position on the rack per the real-world lineup as seen in FIG. 58. If the network has Points-Of-Presence (POPs) where leased fibers or DWDM bandwidths are separated off and routed to local carriers, such sites should be entered. A POP structure can be represented by an Explorer hierarchy similar to the ones created for huts previously described. The example below shows the top levels of a hierarchy for a typical POP structure containing DWDM and Add Drop Multiplex (ADM) equipment. Notice that this structure includes an additional level, a “floor,” which may be used to separate the lower levels by floor and depict the floor location of equipment with x and y dimensions.

Organize the components of the POP into a hierarchy with a floor plan if needed and an equipment set for each lineup. Build the entire structure in the Explorer Workspace, using masters, if possible, for each type of equipment. Use copy and paste to replicate any items that appear in the structure multiple times. After building the entire structure in the Explorer (consisting of one or multiple floors and equipment sets), select the highest level (first floor or equipment set) and send it to the Equipment Workspace. If your highest level is a floor, it will display showing the total area of the floor with icons for any unplaced items in the right side area of the workspace. FIG. 59 shows an example of an empty floor with icons representing its unplaced items displayed beside it. If your unplaced items include equipment sets (for example, lineups), drag and drop those items onto the floor space per their real-world floor location at the POP site. Next drag and drop into each lineup its component items (racks and other rack accessories) from top to bottom in the workspace as shown in FIG. 60.

In most cases when new equipment is added to the database, a master or existing equipment can be copied from it creating the new equipment. If this is not so, equipment can be created from scratch as described herein. In all cases, creating equipment from scratch requires using the New Equipment Wizard to enter basic information including name, type, color, dimensions, and group. In addition, if the equipment has ports, a “port array” defining the number and location of the ports should be created. If the equipment is designed to hold other equipment, one or more “slots” defining the size and location of the cavities that hold the fit-in equipment should be created. If the equipment has other than a straight-through internal signal path, a Functional Object Block (FOB) defining how signals are routed within the equipment should be created.

When creating new equipment from scratch, the first task is using the New Equipment Wizard to enter the equipment name and basic information such as dimensions. To enter basic information have on hand basic information about the equipment, including dimensions and location of ports. From anywhere in FiberBase, select File [symbol] New [symbol] Equipment to display the New Equipment Wizard, as shown in FIG. 61. Click on Next to go on to the next window, shown in FIG. 62. Key in the equipment name. Select equipment type, color, parent, and group if different from those displayed. Group selection determines which large and small bitmaps will be displayed with the equipment name in the system's workspaces. When done in the second window, click on Next to go to the third window, shown in FIG. 63. Key in the equipment dimensions and enter an installation date, if desired. When done in the third window, click on Next to go to the fourth window shown in FIG. 64. In the fourth window, enter any information desired for ownership and purchase of the equipment. When done, click on Finish to enter the equipment in the database.

If the new equipment just created has ports, a port array must now be defined for the equipment to have port-based functionality. To enter a port array, open the Equipment Workspace and select File [symbol] Open. Select the Recent tab, shown in FIG. 65, and select the desired icon. If the equipment for which you want to define a port array is not “recent,” select the Hierarchy tab instead and browse the Explorer hierarchy to find and select the equipment.

The equipment displays without ports in the Equipment Workspace as shown in FIG. 66. Select Tools [symbol] Add Port Array. With the mouse cursor (add array pointer), drag out the rectangular area where you want to add an array of ports, as shown in FIG. 67.

The New Port Array Wizard displays, as shown in FIG. 68. Click on Next to create a port array from scratch, then verify the information in the second window and click on Next again to proceed to the New Port Matrix window, shown in FIG. 69. In the New Port Matrix window, key in the number of ports across and ports down and any other information needed to define the port matrix desired. When done, click on Next.

A New Fiber Port Detail window will display. Enter port insertion loss values, if desired. To do this, click on the “Has Fiber Port Detail” box and then click on the appropriate Edit button to enter a “forward” or “reverse” “Engineering” or “actual” loss values, to be applied to all ports, as shown in FIG. 70.

If any equipment is created from scratch that is designed to hold other equipment, one or more “slots” need to be created to represent the spatial relationship between that item and its child items. A slot is simply a cavity that may hold equipment. A slot has x and y dimensions indicating its size, and x, y and z placement-in-parent dimensions indicating where it is located within its parent.

Any item placed in a slot also has x, y and z placement-in-parent dimensions indicating where it is positioned within the slot. An item may be placed anywhere within a slot so long as it does not overlap any other item.

In the Explorer Workspace, select the item containing the slot to be created. Using the right-click menu, select File [symbol] New [symbol] Slot to display the New Slot Wizard basic attributes window, shown in FIG. 71. Key in a slot name. Select equipment type, color, parent, and group if different from those displayed. Group selection determines which large and small bitmaps will be displayed with the slot name in the system's workspaces.

When done in the first window, click on Next to go to the slot physical attributes window, shown in FIG. 72. In the Dimensions field, key in the slot Width and Height. In the Placement in Parents field, key in x and y dimensions to indicate where the slot is located with respect to the bottom left corner of the parent on the selected side. If the slot is designated to hold a child item that is reversed in orientation when placed in the slot, click on the Flipped box in the upper right of the window. This applies to various types of plug-in modules that are plugged in in one orientation on one side of the chassis, and flipped over on the other side of the chassis. When done, click on Finish to enter the new slot in the database.

If the created equipment has an internal signal path that is other than straight-through from front to back, additional information telling the system how a signal entering the equipment is routed through it needs to be entered. This is done using a Functional Object Block (FOB). Within the regions hierarchy an FOB is a level immediately below the equipment it pertains to.

A typical FOB has a single root “pad” for each input of an internal signal path and a “leaf pad” for each branch. A pad is a pictorial representation of a point where signal paths join with or diverse from one another. Each pad may be given wavelength-specific attributes.

In an FOB diagram, as shown in FIG. 73, an FOB is an equipment-specific diagram with input ports on one side, output ports on the other side, and with lines connected between input and output ports to indicate how signals are routed within that particular equipment. Translated into database relationships, this information provides the system with the mapping needed to propagate a signal or transport through that piece of equipment or (using multiple FOBs) through multiple pieces of equipment.

To create a functional object block in the Explorer Workspace, select the equipment for which you want to add an FOB, then select Send to [symbol] FOB Workspace from the right-click menu. The equipment displays in the FOB workspace, as shown in FIG. 74, with all front side ports listed on the left and all back side ports listed on the right. Pass through ports are not listed because, by definition, they have a straight-through internal signal path and, therefore, do not require an FOB. Spatially arrange the ports so that all input ports (whether “front” or “back”) are listed on the left and all output ports on the right. To do this, simply drag over the ports to move and pull them across from one side to another. In the example shown in FIG. 75 all of the front ports with prefix OUT have been moved across to the right side.

After arranging ports correctly with input on left side and output on right side, select Edit [symbol] Select All to select all the ports on both sides of the display. Select File [symbol] New to display the object type dialog, from which select FOB. From the Kind pulldown list, select a kind indicating the function of the branching being entered (for example, splitter/mux), check the other entries, and select Next to go on to the next window.

The New FOB PAD Basic Attributes window displays with a branching bitmap as shown in FIG. 76 indicating the kind of FOB that has been selected. Based on FOB kind, other fields may or may not be available for use. This window represents a branching in terms of an input “root” pad and one or more output “leaf” pads. “Pad” is just a term for the graphical object representing the input or output point of a signal path in an FOB diagram. If desired, wave-length-specific attributes for any pad can be entered. To do this, use the pulldown lists provided to select an attribute, then type an entry or click on the Edit button to set a new value (manner of entry differs for different attributes).

When done with number of leaf pads and attributes, click on Next to go on to the next window. The window that then displays, labeled FOB Port to Pad Connections, indicates the complete configuration of FOBs, ports, and pads selected. To connect the items as indicated, first verify that there is a check mark in the Make Connections check box (or put one there), then click on Finish. The connected FOB or FOBs display in the workspace is shown in FIG. 77.

After completing one instance each of all basic structures and equipment masters required for the network, the database can be populated with these basic items. Doing this is a matter of simply copying items and pasting them into the structure where desired. After pasting in the items, they can be renamed and edited as required for the new item.

After replicating basic structures throughout the network infrastructure model, fine-tune your structural detail by moving structures with the Regions hierarchy, moving structures on a map, or by adding or editing attributes. To move structures within the regions hierarchy select the structure you want to move, right-click on the item and select Cut from the right-click menu, and select the item you want to paste into, then right-click on the item and select Paste.

To move structures on a map, click on the structure to move and drag it to the desired location. To edit or change attributes in the Explorer Workspace, select the structure to edit, select the item attributes tab in the right area of the workspace, and edit attributes as desired, then click on Save.

A network infrastructure model consisting of regions, structures, routes, and sheaths, with all structures containing structural detail representing the physical organization and equipment within them has now been created.

Adding Customers and Premises

Customers can now be added to the network infrastructure model. This involves creating database entries for customer accounts, adding mid-span splices to customers to represent splice points where one or multiple fibers are broken out of a sheath and routed to a customer, and creating customer premises representing the physical organization and equipment at customer sites.

A “customer” is assumed to be a business, not an individual or residence. Thus a “business” object, of type “customer,” is used for most customer accounts. In cases where a customer is not a business, a “person” object can be used. Customer accounts serve as repositories of the expected information such as customer name, address, and contacts. A customer premise is simply a type of structure in the Regions hierarchy. A customer premise structure represents a site such as a splice vault where the network interfaces with a customer system.

For customers and customer premises, gather all pertinent information identifying customers, the facilities leased to them, and the physical organization and equipment contents of sites of interface between the network and customer networks. For a summary, see Table 8, below.

TABLE 8
Source Information for Route Segments and Sheaths

| TYPE OF | |
|---|---|
| INFORMATION | DESCRIPTION |
| Customer records | Paper or electronic records indicating customer name, |
| | address, email address, website, contact person, billing |
| | address, etc. |
| Leased facilities | Paper or electronic records identifying any sheaths, |
| records | conductors (fiber or copper), and signal spectrums (for |
| | example, a particular DWDN wavelength). |
| Customer premise | Paper or electronic records indicating what exists at |
| drawings, of | specific customer premises (outdoor enclosures, |
| diagrams, or lists | splice or termination panels, and so on. |
| equipment | |

To prepare the source information for entry into the system, organize the customer information using the same scheme as used in the Regions hierarchy in the Explorer Workspace. Go through the windows of the New Business Wizard noting the main items of information. Decide which items are needed for the network needs. Decide on a scheme for identifying customers in the database. The customer names should correspond with real-world names, but may also reflect any necessary network distinctions. Consider the use of “groups” to distinguish between different categories of customers. Each group can be associated with a unique icon so as to be identifiable as a group in the Explorer workspace and other workspaces. Take note of customer premises that are similar to one another in physical organization and equipment content. Identify basic types that can be used as clones for others. Customer premise structures are just another type of structure in the Regions hierarchy and can be copied and pasted to replicate such structures, throughout the network infrastructure model. Decide on a scheme for using color. Each business (customer) has its own color, assigned in the wizard when the item is created. Also, as just mentioned, each item is assigned to a “group,” and each group also has a color designation. Color display by group can be used to visually separate different categories of customers.

Information on customers may separate into five types of objects: businesses, mid-span splices, customer premises, signals, and virtual cables. For details on these items, refer to Table 9 below.

TABLE 9
Object Types That May Contain Customer Information

| OBJECT | |
|---|---|
| TYPE | DESCRIPTION AND HOW CREATED IN FIBERBASE |
| Business | Identifies a customer business, stores information about the |
| | customer, and provides the core item that is associated with the |
| | other items listed below to provide a means of querying |
| | information by customer name. A customer business may be |
| | created from anywhere in the system by selecting |
| | File [symbol] New [symbol] Business to use the New Business Wizard. |
| Mid-Span | Provides a means, in the software scheme for sheaths, to break |
| Splice | one or more “conductors” (fibers) out of the sheath and direct |
| | them to a mid-span structure. Mid-span sheaths may be created in |
| | the Map Workspace using the Utilities [symbol] Cleave Sheath function. |
| | A mid-span splice must be created at a structure. The mid-span |
| | splice divides the cleaved sheath into two sheath segments. |
| Customer Premise | Provides a means of representing the equipment existing at the |
| | demark between your network and the customer. A customer |
| | premise is a structure of type customer premise. Customer |
| | premises may be created from anywhere in the system by |
| | selecting File [symbol] New [symbol] Structure to use the New Structure Wizard. |
| Signal | May be defined as an end-to-end facility (for example, one |
| | DWDM channel) and identified as being owned, leased, or |
| | assigned to a specific customer. Signals can created from |
| | anywhere in the system by selecting File [symbol] New [symbol] Signal to use |
| | the New New Signal Wizard. Signals can also be grouped into |
| | signal sets and associated as such with a customer. |
| Virtual Cable | Is a user-selected grouping of fibers that can be used in some |
| | cases to identify a portion of a ring assigned to a particular |
| | business such as an office park. (Virtual cables may also be used |
| | for other organizational purposes.) A virtual cable may be |
| | created from anywhere in the system by selecting |
| | File [symbol] New [symbol] Virtual Cable to use the New Virtual Cable Wizard. |

A “customer business” is a database object used to store information identifying a particular business that receives network services. After being created, a customer business can be associated with a customer premise to indicate the physical organization and equipment at the customer demark.

From anywhere in the system, select File [symbol] New to display the object selection dialog, then select the Business object, as shown in FIG. 78. Upon this selection the New Business Wizard displays. In the New Business Basic Attributes window, shown in FIG. 79, type in the customer name and select “Customer” for business type. Pick an existing group or create a new group to categorize a particular subset of customers. When done, click on Next. A New business Geographic Attributes Window will display as shown in FIG. 80, key in all available information and click on Next. Then a New Business Contacts window as shown in FIG. 81 displays, click on the Add button to add a contact person, if desired, or click on New to create a new contact person entree. When done, click on Finish. Continue the same steps to make create accounts for other customer businesses if desired.

A “mid-span splice” is used to represent a real-world situation where a sheath is broken into, somewhere other than at either end, for the purpose of splicing off one or more fibers for use at a customer site.

Mid-span splices are created using the Cleave Sheath Segment function which is available on the Utilities or rightclick menu when a sheath segment is selected. To create a midspan splice, three components required to set up the association in the software must be identified, the sheath segment being cleaved; the conductors being cleaved (within the identified sheath); and a structure or landmark (indicating where the splice chip is physically located).

In the Map Workspace, rightclick on the sheath segment to splice into and select Cleave Conductor from the rightclick menu as shown in FIG. 82. In the Cleave Sheath Segment window shown in FIG. 84, select either a landmark or a structure where the sheath will be cleaved, then click on Next. In the Two Sheath Segments window shown in FIG. 84, key in Length, Start Mark, and End Mark for each sheath segment. Also, if desired, key in numeric values indicating how much slack is stored at the start and end of the sheath and at the splicing location. In the Choose Conductors to Cleave window shown in FIG. 85, browse to find the conductors to be cleaved and click on the right arrow button to move them into the Conductors box, then click on Finish. To view the cleaved conductors, if desired, rightclick on the sheath (not sheath segments) in the Explorer Workspace and select Send to Virtual Cable Workspace as shown in FIG. 86, from the right click menu.

A customer premises is a “structure” identified as type “customer premise” when created. Except for this, a customer premises is identical in makeup and function to the other structures created as previously described. The purpose of a customer premises is to represent the physical organization and equipment content of a specific site where the network interfaces with a customer system. A customer premises is often a simple structure as will be described. Select a standard customer premise that are will serve well as a template for replicating others of the same kind. In the Map Workspace click on the add structure icon, then click on the map location where a customer premise is to be added. A New Structure Wizard will display as shown in FIG. 87. From here select customer premises for type, then click on Next to proceed to additional windows to enter any additional information regarding the customer premises. When done, click on Finish to display the new customer premises structure in the Map Workspace as shown in FIG. 88. Select the new customer premises and select Send to [symbol] Explorer Workspace from the rightclick menu as shown in FIG. 89. In the Explorer Workspace, use the rightclick menu New command to build the detail levels for the customer premises structure. After completing the entire structure, send the highest level item to the appropriate workspace to position the items within the structure. For example, if the top level is a floor, send it to the Floor Workspace.

After completing one customer premises, continue to create other basic kinds for use in replicating others. Whenever possible, copy and paste using existing Regions hierarchy fragments.

Next, connecting and organizing sheaths will be described. Sheathes can be connected one at a time as the need arises or alternatively, a systematic approach can be employed to go through all of the sheaths and connect them in a single organized effort.

The basic strategy presented is to focus on one region at a time, organizing connections in terms of five basic types:

Straight-through splices;

Straight-through connections to connector panels, as in Outside Plant (OSP) entry;

Intra Facility Cable (IFC) connections such as splice vault to inside connector panels;

Patch cord connections such as connector panels to fiber optic equipment; and

Connections to mid-span splices.

As part of this process, it is encouraged to use “landmarks” to record the length of slack available along the sheath in identified structures. Technically, a landmark is a logical association between a specific sheath and a specific structure with a numeric value indicating the amount of slack coiled within that structure.

“Start slack” and “end slack” may also be entered for each sheath at the origin and termination structures, respectively. These slack values do not require landmarks.

For sheath connections and organization, gather information such as summarized in Table 10, below.

TABLE 10
Source Information for Route Segments and Sheaths

| TYPE OF | |
|---|---|
| INFORMATION | DESCRIPTION |
| Long Route | Any diagrams showing physical location of |
| Diagrams | sheaths and summarizing sheath connections, |
| | especially for cases where connections are straight- |
| | through such as in straight-through splices along |
| | long haul routes. |
| Sheath | Listings of all conductors within a sheath and what |
| Breakdowns | they are connected. These are more useful for |
| | sheaths connected to multiple pieces of equipment. |
| Floor Plans | Floor plans or diagrams summarizing Outside |
| and Interior | Plant (OSP) termination at a particular structure |
| Use Diagrams | and interior routes and connections for Intra |
| | Facility Cable (IFC). |
| Patch Cord | Diagrams summarizing routing of patch cords |
| Diagrams | between equipment within a particular structure. |
| Summaries of | Any documents pertaining to special arrangements |
| Leased, Vendor- | such as leased lines, vendor-owned lines, lines |
| Owned, or | assigned to particular businesses or people, etc. |
| Special Case | |
| Conductors | |

Follow these steps in sequence to prepare the source information for entry into the system. Organize the source information into map areas defined by regional boundaries for lower-level regions. Organize the source information further into the types summarized in Table 10 above. Decide on a scheme for use of virtual cables. Sheathes have a hierarchical inner structure composed of binders and conductors. These are generic terms corresponding to any real-world sheath sub-units such names as buffers and fibers. Generic names are used to cover multiple types such as ribbon-structured fiber optical cable and coaxial cable. Connections are made between a conductor and an equipment “port,” setting up an association in the database that may be used when needed by the software to display continuous physical paths from end to end, as is done in the Sheath Segment Topology Workspace.

The main workspace used for connecting conductors and ports is the Connection Palette. In a typical application, a sheath and equipment, or multiple sheaths and equipment, are displayed in this workspace to be connected to one another.

In the Connection Palette, conductors and ports can be connected in individual pairs or “mass-connected” within an area dragged out with the mouse. Since a mass-connect involves a pictorial alignment, preparing for a mass-connect may involve arranging items spatially in the palette, which can be easily done with the mouse by dragging items. Individual connections between a conductor and port may also be made from anywhere using the rightclick menu “Quick Connect” function.

“Virtual cables” provide a means of designating a subgroup of conductors for a specific purpose such as being leased to a particular customer. Any arbitrary subgroup may be defined, either within an individual sheath or within multiple sheaths.

Sheath inner structure, usually assigned based on sheath master (if used) may be edited using the Sheath Workspace. This workspace allows you to rearrange buffers, conductors, and color scheme within an existing sheath.

Other workspaces allow investigation of existing sheaths and topologies of sheaths. The workspaces are covered in Table 11.

TABLE 11
Terms for Sheath-Related Functions

| ITEM | DESCRIPTION |
|---|---|
| Sheath | A representation of one continuous fiber optic or coaxial |
| | cable. |
| Sheath | Synonymous with “sheath” above, except when a sheath is |
| Segment | severed by a mid-san splice, in which case it becomes two |
| | sheath segments. |
| Binder | Highest level sub-unit of a sheath comparable to a ribbon or |
| | buffer tube in a fiber optic cable. |
| Conductor | Physical medium capable of carrying a signal (for example, |
| | a fiber) |
| Mass- | Function connecting a set of conductors and ports at the |
| Connect | same time |
| Start Slack | Slack associated with a sheath at its origin structure |
| End Slack | Slack associated with a sheath at its termination structure |
| Landmark | Association between a structure and sheath at some point |
| | along the sheath enumerating slack length kept at that |
| | structure. |

This description assumes a systematic approach based on focusing on one region at a time and connecting sheaths in each region using four basic types of connections:

Straight-through splices (such as commonly used at a splice point on a long-haul route to connect two consecutive sheaths.

Straight-through connections to connector panels, such as commonly used in bringing outside plant (OSP) cables into a hut or central office.

IFC or patch cord connections, such as commonly used, within a hut or central office, to route circuits from connector panels to fiber optic equipment.

Connections to mid-span splices, such as commonly used to connect a customer premise to fibers broken off a sheath.

For each of these four types, a procedure is presented below. In most cases, you will wind up doing a mix of the four types rather than doing all of the same type at the same time. While connecting sheaths, you should also record slack, covered in a fifth procedure below.

A typical straight-through splice involves two sheaths and one or more splice trays, connected in numerical order (conductor 1 to splice tray 1, position 1; conductor to splice tray 2, position 2, etc.). For a more detailed description of performing such a connection reference may be had to U.S. Provisional Serial No. 60/251,254 which is hereby incorporated by reference.

Rightclick on the structure and select Send to [symbol] Explorer Workspace to identify the structure in the Explorer Workspace hierarchy.

Adding Transport and Signals

The system can be used to determine how the network is organized for carrying signals (i.e., transport) and what kind of signals are being sent over your network (i.e., signal). Briefly, a transport represents the physical medium carrying a signal and a signal represents a signal as commonly understood as a state applied to the medium to convey information.

Transports are defined as a topology of ports and conductors as shown in FIG. 90. Signals are defined as two ports only, the ports on either side of the signal as indicated in FIG. 91. A signal can be placed within a transport, in the Explorer Workspace hierarchy, to indicate that that signal is conveyed by that transport. Multiple signals within the same transport can also be arranged into a hierarchy to represent a signal nesting such as three OC1s within an OC3 signal. Transport sets and signal sets can be created which may be used to group items such as forward and reverse signals of the same circuit.

To prepare for entering information on transports and signals, gather information such as summarized in Table 12, below.

TABLE 12
Source Information for Transports and Signals

| TYPE OF | |
|---|---|
| INFORMATION | DESCRIPTION |
| Port- | Listing or drawings of injection ports for transports |
| Transport | (ideally with details on launch power and identification |
| Summaries | of signals being transmitted). |
| Signal | Listing of signals being transmitted with information |
| Summaries | on ownership, leasing, or assignment of signals. |
| Summaries | Text description, tree-structure diagrams, or any |
| of | similar material indicating relationships between |
| Transport | individual transports and signals (specifically, |
| or | transports grouped as a circuit, signals sharing a |
| Signal | common function, signals conveyed by way of |
| Organization | particular transports, signals nested within one |
| | another). |

To prepare the source information on transports and signals for entry into the system organize the source information into map areas defined by your regional boundaries for lower-level regions, within each map area, organize the source information into folders for different start and end structures for transports and signals. Within each folder, separate the source material into two groups for transports and signals. Identify transports that function in conjunction with other transports (for example, forward and reverse paths for the same circuit, or active and protect paths for the same circuit). Identify signals that are nested within other signals. Decide on a scheme for naming the four types of items that you'll be working with: transports, transport sets, signals, and signal sets.

A “transport” represents a physical path of ports and conductors capable of carrying one “leg” (regeneration) of a signal from point of interjection to point of reception. A transport may not span multiple legs of a signal. A transport is defined by identifying the injection port in a New Transport Wizard. The rest of the transport topology is found based on the associations of ports and conductors contained in the database. The topology ends when the chain of conductors and ports dead-ends or when it leads to a port identified as a receiver port by a receiver type FOB.

FOBs also come into play in transport topologies whenever a transport passes through a port identified as a passive multiplexer or splitter (such as WDM applications). The system finds all such branchings and includes them in the transport, as shown in FIG. 92. If the injection port identified when creating a transport (such as the port pointed at in FIG. 92) is one of multiple branches leading onto a common conductor (such as the 5×1 multiplex shown), the transport topology will include all injection ports leading onto the common conductor (as with the five injection ports shown in the example). A “signal” represents a signal as commonly understood in the real world (for example, an OC-48 signal transmitted between two hubs).

A signal begins at a point of origin where its information is assembled and ends at a point of termination where its information is disassembled. What lies between is not defined.

Signals may be placed into transports to indicate physical path, however. In addition, within a transport, signals may be hierarchically arranged to indicate signal nesting, such as shown in FIG. 93.

Transports and signals may, also, both be organized into “sets.” Both types of sets are arbitrary groupings used to identify items that together compose a single circuit or set of related circuits.

Since transports and signals have enough similarities to create some possible confusion, and are often used in conjunction with one another, it is important to understand the differences between them. Table 13, below, lists comparisons.

TABLE 13
Comparison of Transports and Signals

| FEATURE | TRANSPORT | SIGNAL |
|---|---|---|
| Starting Port | A transport begins at the port | A signal begins at an identified |
| | (called Injection Port) where the | port (Port #1 in the Signal |
| | physical signal is inserted into | Attributes) where the information |
| | the conductor. | content of the signal is assembled |
| | | and put onto a conductor. |
| Total span | A transport may span only one | A signal may span multiple |
| | hop of the physical signal (for | transports (for example, from one |
| | example, from Op Regen to Op | local region hub to another in a |
| | Regen in a long haul network). | long haul network). |
| Ending port | A transport is “propagated” by | The ending port for a signal is |
| | the software using database | explicitly defined by the user |
| | associations of ports and | creating the signal (it is Port #2 in |
| | conductors to follow along the | the Signal Attributes). Port #1 |
| | path of the transport. The | and Port #2 may be thousands of |
| | propagation ends when the | miles apart, as in the case of a |
| | software either can go no further | long haul signal being transferred |
| | or encounters a port identified as | between hubs in different |
| | a receiver by a receiver type | geographical locations. |
| | FOB. | |
| Mid-Span Items | Mid-span items (ports and | Mid-span items in a signal are not |
| | conductors) in a transport are | known. They can be identified by |
| | determined by the software and | association by placing the signal |
| | can be displayed as a topology as | in one or more transports. |
| | soon as the transport is created. | |
| Set | The purpose of a transport set is | The purpose of a signal set is to |
| | to identify transports that | identify signals that work together |
| | together provide the physical | as a circuit or as a set of related |
| | media for a circuit or set of | circuits. |
| | related circuits. | |
| Signal Hierarchy | Signals may be arranged | Signals may not be arranged |
| | hierarchically within a transport | hierarchically within either a |
| | (but not within a transport set) to | signal or a signal set. |
| | indicate signal nesting. | |

The usual way to create a transport is to begin by selecting the injection port of the transport. First, display the equipment or its parent rack or lineup in the Equipment Workspace. Next, find the injector port for the transport in the pictorial display. Right click on the point of injection port and select New [symbol] Transport from the rightclick menu. Shown in FIG. 94 is an example, an Add-Drop Multiplex OC-1 output.

A multiple windowed wizard will appear. In the first wizard window, shown in FIG. 95, key in a transport name and provide other information as desired. In the next window shown in FIG. 96, indicate whether the fiber transport detail (in the form of a spectrum of wavelength vs. launch power values) is to be added. If so, click on “Has fiber transport detail,” then on the desired Edit button, as shown. In the Edit Spectrum Values window shown in FIG. 97, use the buttons to add, edit, or remove spectrum entries, each consisting of one wavelength vs. launch power association. When done in the Edit Spectrum Value window, click on OK to return to the New Fiber Transport Detail window. When done in the New Fiber Transport Detail window, click on Next.

A New Transport Inventory Attributes window shown in FIG. 98 displays. Indicate whether the transport is assigned, leased, or owned, whether it is lit, protected, or faulted, whether an installation date is planned, and whether it should be placed in an existing transport set.

After the transport is completed, the transport name will display selected in the Explorer Workspace. To view the completed transport pictorially, rightclick on the transport name and select Send to [symbol] Transport Topology Workspace. The transport displays as shown in FIG. 99.

A transport set is a single-level grouping of transports created to identify the transports as together composing a circuit or set of related circuits. To create a transport set from any location, select New [symbol] Transport Set to display the “What would like to create?” window shown in FIG. 100. Select Transport Set as the object type.

A first New Transport Set Basic Attributes window displays, shown in FIG. 101, key in a transport set name and enter other values as desired, then click on Next. In the New Transport Set Inventory Attributes window shown in FIG. 102, indicate whether any business is the assignee, leaser, or owner of this transport set. Select or create a group and enter any other information desired, then click on Next. In the final window shown in FIG. 103, use the Add button to add one or more transports to the list of transports in the set. When done, click on Finish to save the transport set in the database.

Creating signals, organizing signals into signal sets, and putting signals in transports are done using separate procedures as will be described. In creating a signal, identify starting and ending ports, called Port #1 and Port #2, respectively. What lies between these ports is left undefined.

To create a signal from anywhere in the system, rightclick on the starting port for the signal and select New [symbol] Signal from the rightclick menu. Shown in FIG. 104 is an example using a port displayed in the Equipment Workspace. In the “What would like to create?” window shown in FIG. 104, verify that the pulldown list is positioned on “Signal” then click on OK. In the first New Signal Basic Attributes window, shown in FIG. 106, key in a signal name, select a signal type, and identify the ports on either end of the signal. After identifying the ports, identify a group in this same one or click on New to create a new group. When done, click on Next. In the New Signal Set Inventory

Attributes window shown in FIG. 107, indicate the assignee, leaser, or owner of this signal, if any. Enter any other information desired and click on Finish to enter the signal in the database. To associate the new signal with a particular transport, copy and paste the signal into the transport.

You can use a “signal set” to group together two or more signals for the purpose of identifying them with as a set of signals as composing a circuit or set of related circuits. To create a signal set from any location, select New [symbol] Signal Set to display the “What would like to create?” window shown in FIG. 108 with the pull down selection list position on the “Signal Set” object type. Click on OK. In the first New Signal Set Basic Attributes window, shown in FIG. 109, key in a signal set name and enter other values as desired, then click on Next.

In the New Signal Set Inventory Attributes window shown in FIG. 110, enter a TEO (Technical Engineering Order) number, if one is available (not required), and identify the assignee, leaser, or owner of the signal set (if any). When done, click on Next. In the Signals in the Signal Set window shown in FIG. 111, click on Add to add the first signal. A browse window displays as shown in FIG. 112. Browse to find and select the signal you want to add to the signal set. Continue adding signals until all signals are present in the set. To remove a signal from the signal set, select the signal name in the window and click on Remove.

A signal, or multiple signals, can be put inside of a transport to indicate that the signals are conveyed by that transport. This is a logical parent-child association such as equipment and ports. The signals within a transport may also be arranged into two or more hierarchical levels to indicate the nesting of signals (such as in a case where an OC3 signal contains three OC1s, as in the following example). To put signals in a transport in the Explorer Workspace open the Signals folder to list the signals that you want to place in the transport. Rightclick on the first signal that you want to put in the transport and select Copy from the rightclick menu as shown in FIG. 113. Rightclick on the transport name and select Paste from the rightclick menu as shown in FIG. 114. Continue copying and pasting signals until all are present in the transport. When done, verify that all the signals copied are present within the transport.

After creating transports, transport sets, signals and signal sets, individual items can be revisited to fine-tune the the information using the procedures referred to in Table 14 below.

TABLE 14
Fine-Tuning Procedures

| TO DO THE | |
|---|---|
| FOLLOWING | USE THIS PROCEDURE |
| Edit attributes for | Select the item name in the Explorer |
| a transport, transport set, | Workspace and click on the attributes tab. |
| signal, or signal set. | |
| Put the same signal | Create one instance of the hierarchy and |
| hierarchy in | then copy the parent signal and paste it into |
| multiple transports. | the other transports. |
| Remove a signal from | Rightclick on the signal name (below the |
| a single hierarchy | transport) and select Clear from the |
| within a transport. | rightclick menu. |
| Change attributes for | Edit any instance of the signal in the |
| a signal that appears | Explorer Workspace; all instances will be |
| in multiple transports | changed in the same way. |

Use of the System

The system's basic use encompasses three main types of activities: finding information; changing information; and reconfiguring features and settings such as the view used for the system's desktop, baloon info content, display of info tabs, and preference settings.

Finding information is easy and flexible due to the relational nature of the database. The main query tool, the Finder, can be started up from any workspace by clicking on the Finder icon (see 40 in FIG. 7) in the Launch toolbar. The Finder permits queries to be limited by name, description, database object type and group, as well as by specific attribute values using a filter. Queries can be limited to a specific geographical area by dragging out an area on a map and then starting up the Finder.

Changing information is also easy and flexible because the starting point for most changes can again be any workspace where the object or objects to be changed can be selected. Clicking on the Info Palette button (see 42 in FIG. 7) starts up the Info Palette tool which can be used to change object attributes for a selected object. Map properties of database objects, such as locations of structures and drawn paths of route segments, can be easily changed by using mouse functions in the Map Workspace as will be described. To perform a query in a defined area, click on either the radius query tool or marquee query tool (see 44 and 46 in FIG. 8 respectively) and with the mouse drag out the area on the map, as shown in FIG. 115. The Finder displays, as shown in FIG. 116. The Finder can be accessed from a map as described above or from anywhere in the system by either selecting Windows [symbol] Palettes [symbol] Finder or click on the Finder button in the Launch toolbar. For most queries, use the Basic tab, as follows. In the Name field, key in a unique name or use one or more wildcard characters (*) to define a range of names to be queried.

In the Description field, key in a unique description or use one or more wildcard characters to define a range of names to be queried. In the Group field, select “any” or a specific type to limit the query by group. In the Type field, select any specific type to limit the query by database object type.

To limit the query to selected database types, use the Advanced tab as will be described hereinafter. Other available finder functions are described in Table 15.

TABLE 15
Finder Tabs

| TAB TITLE | DESCRIPTION |
|---|---|
| Geographical | To limit a query to a geographical rectangular area, define |
| | the area using the latitude and two longitude fields, as |
| | shown in FIG. 117. |
| Options | To limit query output to a specified number of rows, key in |
| | the number of rows in this tab as shown in FIG. 118. |
| Advanced | To limit query to specific object types only, click on the |
| | selection box next to the object name as shown in FIG. 119. |
| | To select a filter for a specific object type, doubleclick on |
| | the object name to display the filter dialog as shown in FIG. |
| | 120. For additional directions, click on the Help button on |
| | the filter dialog. |

To find all objects of the same type find the folder containing objects of the type of interest and select object names individually to review the view tabs for each object. To determine logical children and use of a database object, select the object of interest and select the Contents tab as shown in FIG. 121. This tab shows all objects a level below the selected object in the Regions hierarchy. Then select the Related tab as shown in FIG. 122. This tab shows all objects associated with the selected object.

Using the Explorer Workspace, a route can be found and selected to view the info views for that route. In addition, the route can be sent to the Route Segment Topology Workspace or Sheath Segment Matrix Workspace to display the route pictorially. A pictorial representation of a route consists of boxes representing structures and line representing route segments or sheath segments between structures. To distinguish more clearly between a route segment and a route, each route segment defines the physical path of one segment of a route. A route has no physical path except as defined by its component route segments.

To investigate a route in the Explorer Workspace, select the route name and select Send to [symbol] Route Segment Topology Workspace. To view the Info Palette for any object, select the object and press F2. To view the transport on a map, select Edit [symbol] Select All then select Edit [symbol] Send to [symbol] Map Workspace. The topology displays in the Map Workspace as shown in FIG. 123.

To investigate a span, the Sheath Segment Topology Workspace or Sheath Segment Matrix Workspace can be used to view a representation of all sheath segments in a designated span. To investigate a span in the Explorer Workspace, rightclick on the span name and select Send to [symbol] Sheath Segment Topology Workspace from the rightclick menu, as shown in FIG. 124. Rightclick on the the span name again and select Send to [symbol] Sheath Matrix Workspace. The span displays in the two workspaces as shown in FIGS. 125 and 126 respectively.

To obtain information on any object in the span, select it and press F2 to look at the Info Palette view panes for that object.

To investigate a transport using the Transport Topology Workspace, a representation of an entire, end-to-end transport can be viewed. A transport is an arbitrary collection of conductors, in most cases represending an end-to-end path of conductors through which a signal may be conveyed. Transports are not required to be end-to-end, however.

To investigate a transport in the Explorer Workspace, select the transport name and select Send to [symbol] Transport Topology Workspace. The transport displays in the workspace as shown in FIG. 127. To identify any object, select View [symbol] Baloon Info and point at the item as shown in FIG. 127. To view the information views for any object, select the object and press F2 to display the Info Palette.

A structure is represented as a logical hierarchy in the Explorer Workspace or as a pictorial depiction in the Floor Workspace and Equipment Workspace. To investigate a structure as a hierarchy in the Explorer Workspace, find the structure name and click down through the levels below it to show all objects contained within it. To obtain additional information about any object, select the object and view the information tabs for that object.

To investigate a floor pictorially in the Explorer Workspace, rightclick on the floor name and select Send to [symbol] Floor Workspace. To identify any shape in the floor plan, select View [symbol] Baloon Info and point at the item. To view the information views for any object, select the object and press F2 to display the Info Palette.

For a summary of options for investigating a structure refer to Table 16 below.

TABLE 16
Obtaining Information From a Structure

| TO DETERMINE | DO THIS |
|---|---|
| What a structure | Click down one level in the Explorer Workspace |
| contains at the next | or click on the Contents tab in the Info Views |
| lowest level below it | area of the Explorer. For a list of database objects |
| What a structure | Click down through the Explorer hierarchy or |
| contains at all levels | click on the Sub-Hierarchy tab and click down |
| below it | through the hierarchy displayed on the tab. |
| For a quick view of | First, if the structure has floors, click on the Floor |
| what a structure looks | View tab then click on each floor name |
| like | individually to look at each floor plan. Second, |
| | click on the Equipment View tab, and then select |
| | in turn the equipment set and equipment. |
| For an interactive view | Rightclick on the floor name in the Explorer |
| of what a floor looks | Workspace and select Send to [symbol] Floor |
| like | Workspace. |

A “connection” is represented as an association of an equipment port and a conductor within a sheath. To find a given connection, either the port side or the conductor side can be looked at. To determine if equipment is connected in the Explorer Workspace, rightclick on the equipment and select the Send to [symbol] Equipment Workspace. The equipment displays with its front ports shown as seen in FIG. 128. To view the back ports, select View Back. Click on the Connected State button 50 in the Color toolbar.

Connected parts are identified in a predetermined color. To determine sheath connections in the Explorer Workspace, rightclick on the sheath name and select Send to [symbol] Report Launcher. In the Report Launcher, select the Sheath Connections Report. The Explorer Attributes view or the Attributes view in the Info Palette can be used to edit the attributes for a selected database object.

Advanced use of the system encompasses three main types of activities: finding information; changing information; and troubleshooting network problems. Finding information is easy and flexible due to the relational nature of the database. As previously described, the main query tool, the Finder, can be started up from any workspace by clicking on the Finder icon in the Launch toolbar. Changing information is also easy and flexible because the starting point for most changes can again be any workspace where the object or objects to be changed can be selected. Clicking on the Info Palette button starts up the Info Palette tool which can be used to change object attributes for a selected object. Clicking on the Mass Change button calls up the Mass Change Palette which can be used to change a defined set of database objects at the same time. Map properties of database objects, such as locations of structures and drawn paths of route segments, can be easily changed by using mouse functions in the Map Workspace. Network troubleshooting includes fault marking, generation of selective reports, and use of traces combined with maps to locate problems geographically.

The system can be used to determine network capacity and available bandwidth.

Next references will be added to provide additional information for database objects. Three types of references can be added; documents, drawings, and traces. A document, is a bitmap that can be associated as a whole with one or more database objects but that cannot be edited or gone into other than as a flat file as shown in FIG. 129. By contrast, a drawing is a vector-based drawing composed in the system. Individual shapes within a drawing (for example, a rectangle representing a frame) can be attached to an individual database object, making it function like any object in a workspace. A trace is an OTDR test result file, displayed in a Trace Workspace as a plot of db loss vs. distance along the test path. A typical display also includes a list of “OTDR items” representing the test path through which the trace was shot. Using the Trace Workspace, one can adjust db loss and conductor length values based on the values returned in the trace. A test trace can also be compared against a reference trace and use a reference offset to offset a trace with respect to the test topology. Documents and traces begin as electronic files. When imported into the system, using the functions, as will be described, these files become database objects. Drawings may also be imported or created from scratch in the system using an embedded Visio application.

For a summary of the types of files that may be imported, refer to Table 17, below.

TABLE 17
Source Information for Route Segments and Sheaths

| TYPE OF | |
|---|---|
| INFORMATION | DESCRIPTION |
| Non-System | Existing paper drawings: can be scanned as raster files, |
| Documents | and then imported into the system to serve as |
| | documents. |
| | Existing electronic files: any raster image (for |
| | example, .bmp or .jpg files) can be imported for |
| | documents. |
| Non-System | Existing paper drawings: can be redrawn in the system |
| Drawings | using the Drawing Workspace to produce a Visio |
| | drawing (.vsd file). Existing Visio drawings (.vsd |
| | files): can be imported whereupon they become the |
| | same as any Visio drawing created in the system. |
| Non-System | The system can use any trace file stored in standard |
| Traces | Bellcore format (GR-196). The following vendor |
| | traces have been tested for compatibility with the |
| | system trace view functions: Laser Precision, |
| | Hewlett Packard, and Photon Kinetics. |

To prepare the source information for entry into the system, organize and prioritize all paper source documents that you will be putting into the system as documents. Scan the drawings as bitmaps and store the files in a common folder. Organize all electronic files that you will be putting into the system as documents. Place them in the same folder as above. Organize and prioritize all paper source documents that you will be redrawing in the system. Organize and prioritize all existing Visio drawings (.vsd files) and stencils (.vss files) that you will be importing into the system. Decide on an overall scheme for how and to what extent drawing shapes will be attached with database objects.

A “document” is an image file in raster format. Some examples are files with extension.bmp and jpg. A document is created by being imported from an external file and given a document name. After being imported, a document can be associated with any database object or with multiple database objects. A document as a whole is a single, flat image object. It cannot be internally changed. Only the document's attributes and associations which are external to the image, can be changed.

A “drawing” is an image file in a vector format. It can be of one type only, Visio (.vsd). Visio is the embedded third-party application that provides the main functionality of the Drawing Workspace. In contrast to a document, a drawing consists of drawing shapes such as rectangles and circles that can be sized, moved, labeled, and so on. Once created, a drawing can be made into an interactive display by attaching database objects to drawing shapes. A shape to which a database object has been attached can be used, in conjunction with the File [symbol] Send to menu, to send that object to a designated workspace, palette, or tool. Double-checking on the shape carries the attached item into the item's default workspace. Drawings can be imported from external files or created in a Drawing Workspace.

Table 18 compares documents and drawings.

TABLE 18
Comparison of Documents and Drawings

| FEATURE | DOCUMENT | DRAWING |
|---|---|---|
| File Types | A document can be any raster | A drawing is a Visio vector |
| | file. Some examples are files | file (.vsd). Visio stencils |
| | with extensions bmp, jpg, and | (.vss) can be imported into |
| | tif. | FiberBase, also. |
| Objects | A document as a whole is one | A drawing consists of |
| | object and cannot be | components such as shapes, |
| | internally edited. | lines, and text that can be |
| | | edited. |
| Creation | A document must be imported | A drawing can be imported |
| | from an external source file. | or created in the Drawing |
| | | Workspace. |
| Association | A document as a whole can be | A drawing cannot be |
| | associated with one or more | associated, as a whole, with |
| | database objects. Image | a database object, but |
| | components within a | database objects can be |
| | document cannot be edited or | “attached” to individual |
| | attached to database objects. | shapes within the drawing. |
| Tab | Document View | Drawing View |

TABLE 19
Drawing Workspace Features

| YOU CAN | DESCRIPTION |
|---|---|
| Import a | When a drawing is imported, it displays in the |
| drawing | workspace as an editable file. |
| Create a | A drawing can be created from scratch by dragging |
| drawing | drawing objects from a Visio stencil into the drawing |
| | area. |
| Import a | Visio stencils (in addition to those provided in the |
| stencil | packaged software) can be imported. Visio stencil files |
| | have the extension. vss. |
| Send a selected | When a database object is sent to the Drawing |
| item to the | Workspace, it appears within the workspace as a shape |
| Drawing | correctly labeled per its object name. |
| Workspace | |
| Send multiple | When multiple database objects (such as from a |
| selected items | Contents tab) are selected and sent to the Drawing |
| to the Drawing | Workspace together, they appear in the workspace as |
| Workspace | shapes cascaded upon one another. They can then be |
| | dragged to arrange the drawing. |
| Select a | A database object sent to the workspace will display as a |
| “drawing | “drawing master” (rather than just as a box) if a drawing |
| master” for a | master has been designated for that object. The drawing |
| group of items | master displayed for an object is determined by the |
| | group assigned to that object. Drawing Master is a |
| | group attribute. |
| Export a | A drawing created in the Drawing Workspace can be |
| drawing | exported to an external.vsd file for use with other |
| | applications. |
| Obtain online | The Visio application embedded in the Drawing |
| help | Workspace has its own online manual accessible using |
| | the Help menu. |

Network Troubleshooting

There are two main components of any ODTR test scenario, a test path through which a test pulse is shot and a test result expressed in terms of distance along the test path vs. dB loss.

The Trace Workspace represents these two test components as follows:

The test path is represented as a table-like list of “OTDR items” displayed in the top area of the workspace as shown in FIG. 130. This list consists of items identified by the user as being on the test path.

The test result displays in the bottom area of the workspace as a plot of distance vs. dB loss.

Displaying the OTDR items and trace together in the Trace Workspace (and closing the workspace with them displayed), causes the OTDR items and the trace to be associated in the data base. When that trace is displayed again, the same list of items will be displayed, also. Any or all of the OTDR items associated with a particular trace can be “deleted” from the list at any time, resulting in a new association in the database.

Usually, a list of OTDR items consists of ports and conductors, and is defined by selecting all or part of a transport topology and sending it to the Trace Workspace. However, a port alone or any item with length can be defined as an ODTR item.

When a list of OTDR items and a trace are first displayed together, the distance and dB loss values shown for the OTDR items have no relationship to the distance and dB loss values plotted in the graph. The values shown for the items come from the corresponding database objects. The values shown for the trace come from the trace file. Since, presumably, the list of OTDR items and the trace graph both derive from the same real-world test path, however, the obvious next step is to bring the items and graph into correspondence with one another. This is typically done for a known good trace that is then saved as a reference trace for use in comparison with test traces.

Workspace functions provided for this purpose allow values to be lifted from the trace and put into the ODTR items. For example, using the appropriate mode, you can position the red and blue cursors in the graph to set the db loss and length values for the currently selected OTDR item.

In addition to this change affecting the OTDR items as they are listed in the workspace only, you can “push” such changes back to the database objects. You can also push such changes back to all siblings of the database object (for example, to all conductors in the same sheath).

Table 20 summarizes common terms used with the Trace Workspace.

TABLE 20
Terms Used With Trace Workspace

| TERM | DESCRIPTION |
|---|---|
| OTDR | A list of items (usually ports and conductors) representing the |
| Items | test path through which the trace was shot. |
| Trace | A trace result plotted on a graph of distance (along the test |
| | path) vs. dB loss. |
| Reference | A trace identified as a good trace that other traces should be |
| Trace | compared to. |
| Test Trace | A trace taken to test network function through a test topology |
| | and compared against the reference trace. |
| Injection | Port where the test pulse was inserted. |
| Port | |
| Reference | A value used to offset the trace as displayed in the trace graph |
| Offset | with respect to the X = 0 along the distance coordinate. For |
| | example, an offset of 1000 feet offsets the graph 1000 feet to |
| | the right or the X = 0 distance value on the graph. |

Table 21 below summarizes the main features of the Trace Workspace.

TABLE 21
Main Features of Trace Workspace

| YOU CAN | DESCRIPTION |
|---|---|
| Display a trace alone | A trace displays as a plot of distance vs. dB loss. |
| Associate a trace with a | The list of items usually represents a chain of connected ports |
| displayed list of OTDR | and conductors along the test path. Merely by displaying a |
| items | list of items and the trace together, you associate the list of |
| | items with the trace. |
| Lift distance or dB loss | The workspace mode used for this purpose allows you to |
| values from the trace | select an OTDR item (usually representing a conductor) and |
| graph to the list of items | then use red and blue vertical line cursors to mark off a |
| | section of the trace along the distance coordinate. The |
| | marked off position and length is taken as the conductor |
| | position and length. |
| Push lifted values back | Once you have lifted db loss and length values from the trace |
| to the database objects | to an OTDR item, you can use other functions to push the |
| | same values back to the corresponding database objects. |
| Push lifted values back | You can use can also push db loss and length values back to |
| to the “siblings” of | the siblings of database objects (for example, to all conductors |
| database items | with the same parent). |
| Define a trace as a | When displaying a trace, you can identify it as a known good |
| reference trace | trace for the topology represented by the OTDR items. |
| Define a test group | You can set up a hierarchy composed of a reference trace |
| composed of a reference | parent and any number of test trace children. This combined |
| trace and its test traces | with a Trace Workspace preference will cause the workspace |
| | to display the reference trace when any of the test traces is |
| | displayed. |
| Define an optical offset | You can define a reference offset to offset a trace by a |
| | specified number of distance units from the X = 0 distance |
| | coordinate in the trace graph. |
| Determine distances | Using the red and blue vertical line cursors in the trace |
| between two points on | display, you can measure the distance between points along |
| the trace graph | the distance coordinate. |
| Print a trace | You can print a trace to a file or designated printer. |

Creating and Associating Documents

A “document” is created by importing a raster format file and giving it a document name. When created (or thereafter) a document can be associated with a database object. Importing and associating a document are usually done in a single procedure, as described below. To import and associate a document in the Explorer Workspace, rightclick on the database object, then select New [symbol] Document from the rightclick menu as shown in FIG. 131.

In the Get New Document Data window, shown in FIG. 132 browse to select the source file (any raster file) and verify that the correct item is identified in the Object Type and Object Key fields and click on Next. In the New Document Basic Attributes window shown in FIG. 133, key in a document name (and description if desired). Select or create a group and enter any other information desired, then click on Finish to enter the document in the database. The new document is listed in the Explorer Workspace as shown in FIG. 134. To verify that the document has been correctly associated with the database object, select the database object in the Explorer Workspace and click on the Document View tab as shown in FIG. 135.

Creating drawings and attaching database objects

A “drawing” is a Visio (.vsd) file. A drawing can be created either by importing an external .vsd file and naming it as a drawing or by creating a drawing from scratch in the Drawing Workspace. After creating a drawing, database objects can be attached to shapes within the drawing, resulting in a drawing that functions as an interactive display. Shapes attached to database objects can be used, in conjunction with File [symbol] Send to commands, to send the attached objects to other workspaces, palettes, and tools.

A Visio (.vsd) drawing can be imported into the system using the following procedure. To import a drawing in the Drawing Workspace, select File [symbol] Import [symbol] Drawing. In the Open File window, browse to the folder containing the file to be imported, select the file, and click on Open. In the New Drawing Basic Attributes window, key in a different drawing name, if desired, select or create a group, and supply any other information desired. When done, click on Finished to enter the new drawing into the database. The imported drawing displays from the workspace as shown in FIG. 136.

A drawing can be created from scratch using database objects “sent to” the Drawing Workspace and “masters” pulled from stencils. This procedure illustrates both methods and tells how to import stencils to bring in additional masters. To create a drawing in the Explorer Workspace, rightclick on the first item to be included in the drawing, and select Send to [symbol] Drawing Workspace. The drawing master associated with the sent to item displays in the center of the Drawing Workspace. A database object can be attached to a drawing shape using the following procedure.

To associate a drawing with a database object rightclick on the shape that you want to attach a database object to, and select Attach Database Object from the rightclick menu, as shown in FIG. 137. In the Attach Database Object window, click on the Hierarchy tab shown in FIG. 138, browse to select the database object, and click on OK.

Before an external trace file can be displayed in the Trace Workspace, it must be imported into the system by “creating an OTDR trace,” as will be described. In the process, the trace is named, other trace attributes are entered, and the trace in the data base. To add and define and OTDR trace in the Trace Workspace, select File [symbol] New to display the “What would like to create?” window as shown in FIG. 139. Select OTDR Trace from the pull down selection list and click on OK. In the first window that appears (Get New OTDR Trace Data), browse to select the trace file. When done, click on Next to display the New OTDR Trace Basic Attributes window. Verify or change the trace name, select a trace color, and click on Next. In the next window, verify or change the physical attribute values obtained from the trace file, key in a test date, if desired, and click on Finish. The trace displays in the workspace as shown in FIG. 140.

“OTDR items” represent the test path used for a trace. Displaying the trace and items together causes them to be associated in the database.

To associate a trace with OTDR items with a trace displayed on the Trace Workspace, open the Transport Topology Workspace. Select File [symbol] Open and browse to select the topology composing or containing the test path.

Starting at the leftmost topology item, select the item and press F2 to check the Info Palette for the corresponding database object. If the object is a port, check the Fiber Port Detail Attributers. Enter Fiber Port Detail (Wave length and Insertion Loss) if available and not yet entered. When done, click on Save. If the object is a conductor, check the Conductor Attributes tab. Enter Length and Twist Factor if available and not yet entered. When done, click on Save. Continue editing all the transport items have been checked and provided with values if available. Drag across the topology to select the items you want and select File [symbol] Send to [symbol] Trace Workspace. The OTDR items display as shown in FIG. 141.

When a trace and a list of OTDR items are displayed together in the Trace Workspace, you can lift distance and dB loss values off the trace graph and place them in the distance and dB loss fields for the OTDR items. This affects the listed items only. If desired, you can also “push” the values from the listed items back to the corresponding database objects and their siblings (for example, all conductors in the same sheath). To edit OTDR items using trace values in the Trace Workspace, select File [symbol] Open and browse to select the trace. The trace displays.

To check the current values associated with OTDR items, click on the use cursors to select trace data icon (see 50 in FIG. 141), then click on individual OTDR items an compare the values against the trace display.

To set distance, dB loss, and length values for an OTDR item, select the OTDR item that to be changed. Click on the use cursors to set trace data icon. Hold down the left mouse button to drag the cursor (see 52 in FIG. 141) to the point in the trace where the item begins. Hold down the right mouse button to drag the cursor to the point in the trace where the item begins. Check the values in the list of OTDR items and the position of the item in the trace display. When done, click on the next item for which you want to set values. Continue setting new values throughout the list of OTDR items.

To push values to the database object for any OTDR item, select the OTDR item for which the values that are to be pushed to the database object. Select Utilities [symbol] Push Insertion Loss [symbol] Object to push the insertion loss value displayed for the OTDR item back to the corresponding database object. Select Utilities [symbol] Push Length [symbol] Object to push the length value displayed for the OTDR item back to the corresponding database object.

A trace can be set up with an optical offset to cause the trace to be offset from the X=0 distance coordinate in the trace plot.

For example, consider a case where a reference trace was shot form a manhole 30 meters from termination equipment where a test trace was shot. The test trace can be set up with an offset of 30 meters causing to align correctly with the reference trace as well as with the OTDR items associated with the reference trace. To adjust optical offset in the Explorer Workspace, select the trace and then select the Trace Attributes tab.

After importing and organizing the network reference, the information can be fine tuned using the procedures referred to in Table 22 below.

TABLE 22
Fine-Tuning Procedures

| TO DO THE FOLLOWING | USE THIS PROCEDURE |
|---|---|
| Change database object name for a | Select the item in the Explorer Workspace |
| document, drawing, or trace | then select Rename from the rightclick |
| | menu. |
| Change database object attributes for a | Select the item in the Explorer Workspace |
| document, drawing, or trace | then select the item attributes tab. Change |
| | values as wanted and click on Save. |
| Add an association for a document | In the Explorer Workspace, “drag and |
| | drop” the document name into the name of |
| | the database object with which you want to |
| | associate the document. |
| Add a shape to an existing drawing | Open the drawing, open a stencil |
| | containing the wanted shape, and drag the |
| | shape into the drawing. Name the shape, if |
| | desired, using the text tool and save the |
| | drawing. |
| Offset an existing trace from its associated | Select the trace name in Explorer |
| OTDR items | Workspace and key in the offset in the |
| | Reference Offset field in the Trace |
| | Attributes tab. |
| Add an OTDR item to an existing list of | Display the trace and select Edit [symbol] Insert |
| items | OTDR Item. |
| Disassociate a trace from its reference trace | Select the reference trace in the Explorer |
| | Workspace and de |
| Disassociate a trace for its OTDR items | Select the OTDR item and select Selected |
| | Items [symbol] Delete. |

The system offers several beneficial features for the user. The user can relate an OTDR trace to the physical location on a geographic map in real time. FIG. 142 shows several screen shots that can be displayed on a user's monitor. There is a mapping workspace 100 that shows a geographic area with various structures of the network marked on the map. An OTDR trace workspace 120 is shown below the mapping workspace 100. The user can position the cursor which is in the form of a line 130 at any position on the trace and an indicator 150 in the form of an X appears on the geographic map showing there the geographic location is. Thus as a user moves along the trace a corresponding X moves along the fiber route. The user than thus investigate an event such as spike 170 shown in the OTDR trace which may represent a cable break, for example and know where it is geographically. In addition, a transport topology workspace 140 can be displayed. The topology represents the logical layout of the fiber network. Also, an equipment workspace 16 can be displayed showing a particular piece of equipments, for example.

Also, the user is given the flexibility to choose the set of database attributes to display for an object in a view or list. This also includes a set of calculated attributes which add information not available anywhere else. This allows the user to tailor the views to their needs rather than relying on hard-coded settings defined by the program. Also, objects may be color-coded based on various schemes such as lit fibers, faulted fibers, etc. Color-coding is consistent throughout the various views. In addition, fiber-optic and electromagnetic characteristics of a piece of equipment are defined using functional block diagrams.

An important advantage is that the database from which information appearing I the screen shots is retrieved are all linked together so that a change made in one area is made throughout the system.

The system includes a Splice View Workspace. The Splice View Workspace provides a simplified, pictorial summary of connections between sheath segments. Sheath, sheath segments, spans, structures, routes, and route segments can be sent to the workspace to be displayed in this view.

The system provides a number of topology-related features including the following:

Map Workspace that allows one to query for the total length and other length-related information for linear objects such as routes or spans within a selected region or map polygon. In addition, the sheath segments associated with a selected conductor, transport, or signal can be highlighted. Also, one can create a new route object using multiple linear map items such as streets to define the path of the route segment. Given two structures, the workspace will create the route object using the shortest path through the given polylines.

Shortest Path Palette can be directed to consider paths that could be created by splicing into sheath segments in landmarks. The Shortest Path Palette also will generate a conductor list identifying the conductors within a found shortest path. The list can be used to select the conductors for connecting.

New Port “Path” Calculated Attribute identifies the database objects that would lie above the port in the Explorer Workspace. The path can be displayed in the port shape in workspaces as well as in Balloon info. The path is similar to file path in Windows Explorer.

New “Power Chart View” for a port or conductor displays a graph of power versus wavelength for a selected port or conductor.

New “Cross Section View” provides a cross section view of a route segment, sheath segment, duct, binder, or conductor. The view shows all objects hat in the real world are physically contained within the selected object. For example, a cross section view of a route segment would show any ducts within the route segment, any sheath segments within the ducts, any binders within the sheath segments, and any conductors within the binder.

The workspace shown in FIG. 143 is called “splice view” because it depicts sheath segments as if directly connected to one another—without equipment between them. Connections are shown in lines between conductors. Sheath segments are depicted as if going into structures, but with the connections inside of structures hidden from view.

The Splice View Workspace can be used to obtain a quick pictorial summary of connections. This can be done in any of the following situations:

Select a structure and see all sheath segments going into it and how they are connected to one another.

Select one or more sheath segments and see structure they go into and how the sheath segments are connected to one another.

Select a span and see all sheath segments within the span, structures the sheath segments go into, and connections between the sheath segments.

Select a route or route segment and see all sheath segments within it, structures the sheath segments go into, and connections between the sheath segments.

Options for this workspace include: “collapsing binders” to show connections as lines between binders; “showing” or “hiding” connections; excluding or including landmarks (if included, sheath segments are depicted as passing through them); and using color to highlight various features within the display which will be described in greater detail hereinafter.

A sheath, sheath segment, span, route, route segment, or structure can be displayed as described in Table 22.

To display an object:

1. Select File [symbol] Open. The Open Dialog will appear.

2. From the Open Dialog select the Hierarchy or Recent tab

3. If using the Hierarchy tab, browse to select an object.

4. If using the recent tab, select an object type, if desired, then select an object.

5. Click OK when finished.

TABLE 23
Objects Displayed in Splice View Workspace

| OBJECT TYPE | RESULTANT DISPLAY |
|---|---|
| Sheath | Shows all sheath segments in the sheath, all structures where the |
| | sheath segments terminate, and all sheath segments connected |
| | to the queried sheath segments. Landmarks can be optionally |
| | included in the display. |
| Sheath Segment | Shows all structures where the sheath segment terminates, and |
| | all sheath segments connected to the queried sheath segments. |
| Span | Shows all sheath segments in the span, all structures where the |
| | sheath segments terminate, and all sheath segments connected |
| | to the queried sheath segments. Landmarks can be optionally |
| | included in the display. |
| Route | Shows all sheath segments in the route, all structures where the |
| | sheath segments terminate, and all sheath segments connected |
| | to the queried sheath segments. Landmarks can be optionally |
| | included in the display. |
| Route Segment | Shows all sheath segments in the route segment, all structures |
| | where the sheath segments terminate, and all sheath segments |
| | connected to the queried sheath segments. Landmarks can be |
| | optionally included in the display. |
| Structure | Shows all sheath segments that terminate at the structure and |
| | how they are connected to one another. Landmarks can be |
| | optionally included in the display. |

The basic components of a splice view are structures and sheath segments. Multiple structures will be shown if the queried sheath segment(s) are associated with multiple structures.

Refer to Table 22 below for description of the shapes included in the pictorial view.

TABLE 22
Splice View Workspace Shapes

| SHAPE | SIGNIFICANCE |
|---|---|
| Gray Box | Represents one structure. It will be either a structure where a |
| | sheath segment terminates or (if “includes landmarks” is |
| | enabled) one landmark through which the sheath segment |
| | passes. |
| Oblong | Represents one sheath segment with its hierarchical |
| Rectangles | components, in descending order, binders and conductors. |
| Lines | Represent connections between conductors or (if “collapse |
| Between | binders” is enabled) between binders. Binders are regarded as |
| Con- | “connected” if all conductors within them are connected. |
| ductors | |
| Conductor | Represent conductor state or what happens at the other end of |
| Colors | a connected conductor (for example, “dangling”). For a |
| | description of the colors currently being used, select |
| | View [symbol] Legend. |

The Map Workspace has two important features:

Conductors, Signals, and transports can be sent to the map. The objects are translated to the associated sheath segments (for example, all sheath segments along the leg passing through the selected conductor).

Total length and various other length-related information can be determined, within a selected region or map polygon, for database objects having length.

To highlight a selected conductor, transport, or signal, select the conductor, transport or signal in any workspace; use the Send to function to send the conductor to the Map Workspace.

The Map Workspace has a “Lengths in Region” utility that allows one to obtain comprehensive information, with in a selected region or map polygon, for database objects having “length.”

The comprehensive information includes the following:

A summary page for all included object types. The types to be included are determined by the user using the Edit [symbol] Preferences [symbol] Length in Regions tab for the Map Workspace.

A detail tab for each included database type. Using the detailed view Preferences tab, one can select the attributes included in the detailed view.

Once displayed, the information in the tabs can be printed, or exported for use in a third-party application such as a spread sheet processor. Below are procedural details for using the “Region Lengths” function.

1. In the Map Workspace select Edit [symbol] Preferences.

2. Select the Lengths in Region tab as shown in FIG. 144.

3. Using the list of Database Types on the left side of the tab, click on those you want to be included (to mark them with a checkmark). Unselect those you don't want included.

4. Click on OK.

To perform a total length query,

1. In the Map Workspace, select a region or map polygon

2. Select Utilities [symbol] Lengths in Region.

3. The query displays as shown in FIG. 145.

To Use the Summary Tab

1. After performing a query as described above, select the Summary tab.

2. Interpret the display referring to Table 25 below.

TABLE 25
Summary Tab Columns

| COLUMN | |
|---|---|
| NAME | DESCRIPTION |
| DBType | Database object type for which summary information is |
| | provided in the same row of the display. The object types |
| | included are determined by the Map Workspace |
| | Edit [symbol] Preferences [symbol] Lengths in Regions tab |
| Number | Total number of objects of identified type lying wholly or |
| Objects | partially in the selected region or map polygon |
| All in | Total number of objects of the identified type lying wholly in |
| Region | the selected region or map polygon (subset of Number |
| | Objects). |
| Partial in | Total number of objects of the identified type lying partially |
| Region | in the selected region or map polygon (subset of Number |
| | Objects) |
| Length in | Total mapped length, inside the selected region or mapped |
| Region | polygon, of objects of the identified type. |
| Total Map | Total mapped length, inside and outside of the selected region |
| Length | or mapped polygon, of objects of the identified type. |
| DBObject | Total user-entered length (as opposed to mapped length) |
| Length | inside and outside of the selected region or mapped polygon, |
| | of objects of the identified type. |
| Slack | Total slack length, inside and outside of the selected region or |
| Length | mapped polygon, of objects of the identified type. Slack |
| | length is derived from sheath segment start slack, end slack, |
| | and slack at landmarks. |

In the Map Workspace, one can select two structures and a set of map polylines on the map (such as streets and highways) and generate a new route object from one point to another. The new object will placed on the shortest route between the two structures using the selected polylines.

To create a route object using map polygons, select the two structures on either end of the route you want to create; select any number of map polylines as shown in FIG. 146; select File [symbol] New and use the New Route Wizard to create a new route. The new route displays as shown in FIG. 147.

The Shortest Path Palette has two additional features:

One can now perform shortest path query with landmarks included. When landmarks are included, the query will consider shortest paths that could be created by cleaving sheath segments at landmarks.

The Shortest Path now allows a conductor count to be specified for queries and generates a list of the conductors composing the found shortest path. This list can be used to select conductors for the purpose of sending them to other workspaces or submitting them to other functions.

Including landmarks causes the Shortest Path Palette to consider shortest paths that could be built by cleaving sheath segments at landmarks.

To include landmarks in shortest path queries in the Shortest Path Palette, select Edit [symbol] Preferences. Select the Shortest Path tab. In the Sheath Segment Query box, select Use Landmarks as shown in FIG. 15. Click on OK. IN the Shortest Path Palette, proceed to perform a query using the Utilities [symbol] Calculate Path function.

To include landmarks in shortest path queries in the Shortest Path Palette, select Edit [symbol] Preferences. Select the Shortest Path tab. In the Sheath Segment Query box, select Conductor Count and enter the number of conductors you wan to be included, as shown in FIG. 148. When done, click on OK. Select the Conductor Filter tab, as shown in FIG. 149, and use it to select attributes and associated operations to be used in filtering for a subset of conductors (for example, Leg Is Eng. Lit=0 (true) in the example shown). When done with filters, click on OK. IN the Shortest Path Palette, proceed to perform a query using the Utilities [symbol] Calculate Path function.

The system provides the ability to display a calculated port attribute called “Path” to identify the path of parent objects “above” the port in the Regions hierarchy. Once the attribute is set to display, it display within the port shape and also displays within the balloon info for the port. Both types of display are shown in FIG. 150, though in the example shown, the port shape is not big enough for the entire path to fit inside.

The system has a “Power Chart View” (shown in FIG. 151) that displays for a conductor or port when the object is selected in the Explorer Workspace.

The Power Chart View shows a graph of power versus wavelength indicating signal power at that port or conductor. For any given port or conductor, the power value shown derives from the engineering or actual launch power entered for the injection port of that leg minus accumulated loss from ports, conductors, and FOBs.

To display the power chart view select a port or conductor in the Explorer Workspace and click on the Power Chart tab.

To interpret the power chart view use the X axis of the graph to reference the various wavelength spectrum of interest and use the Y axis of the graph to find the corresponding launch power.

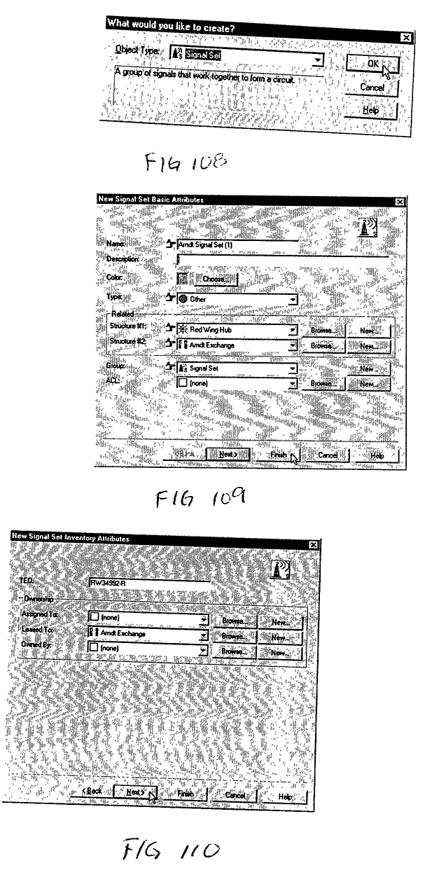

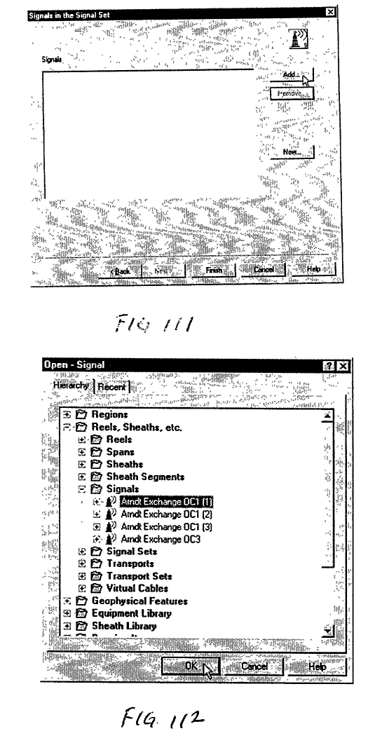

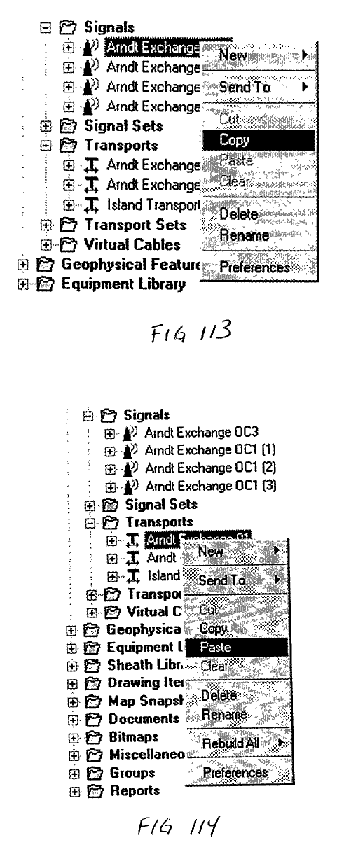

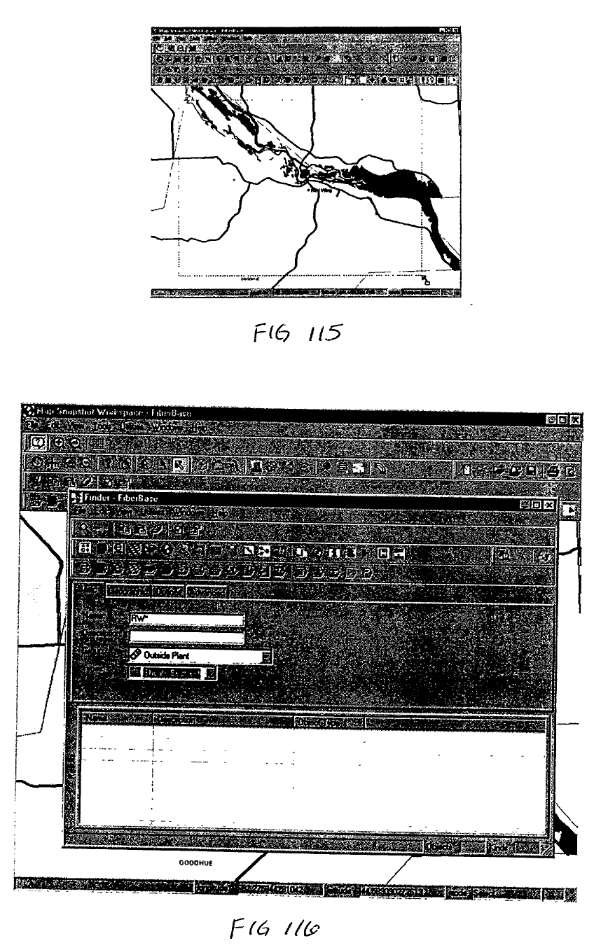

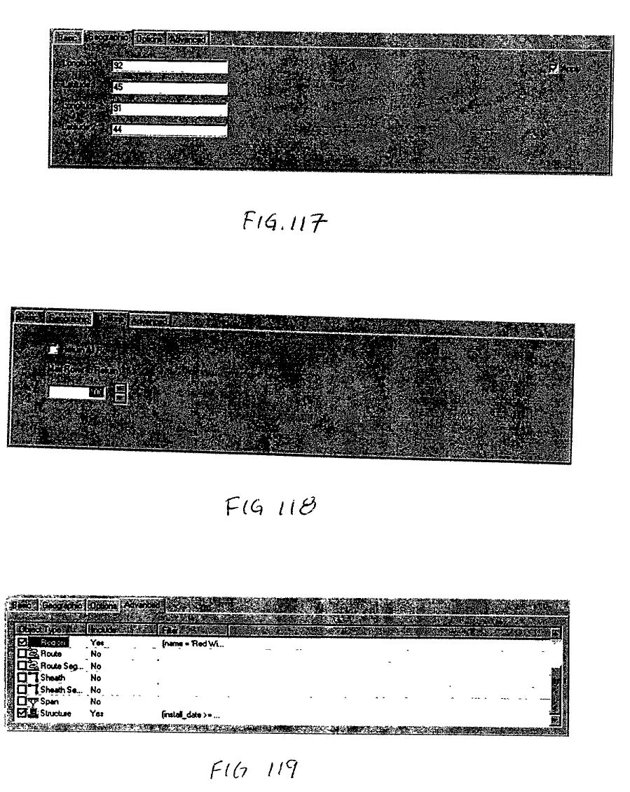

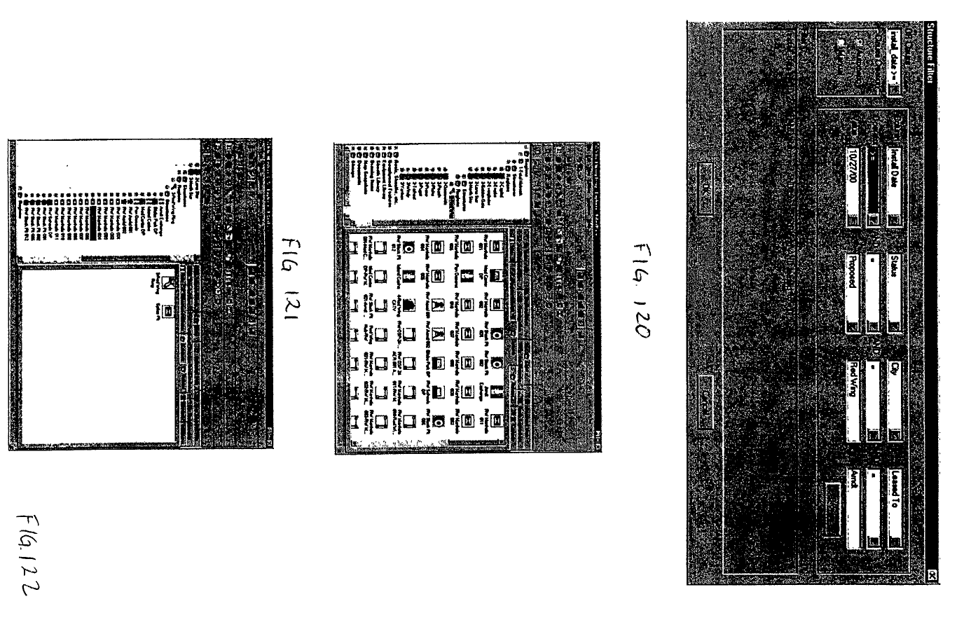

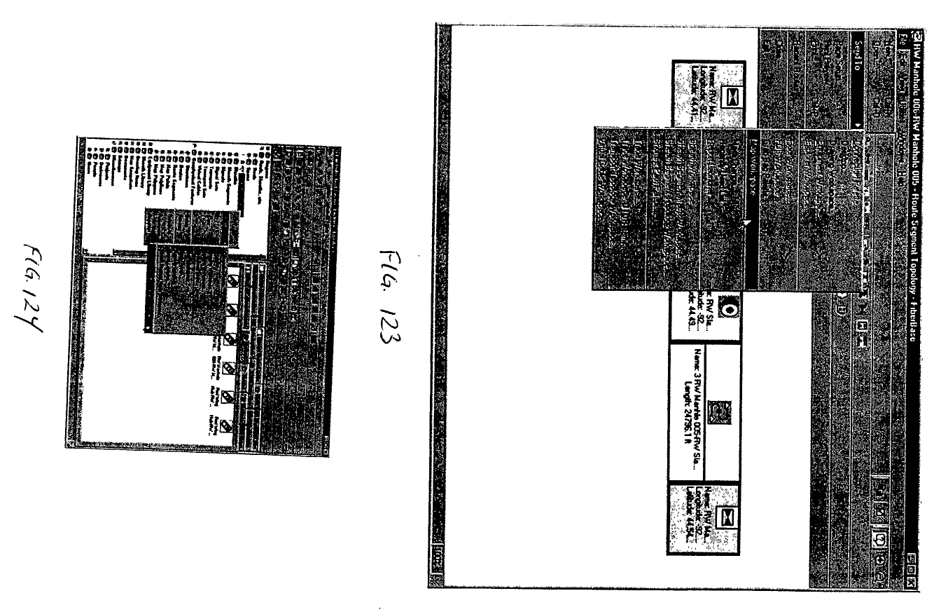

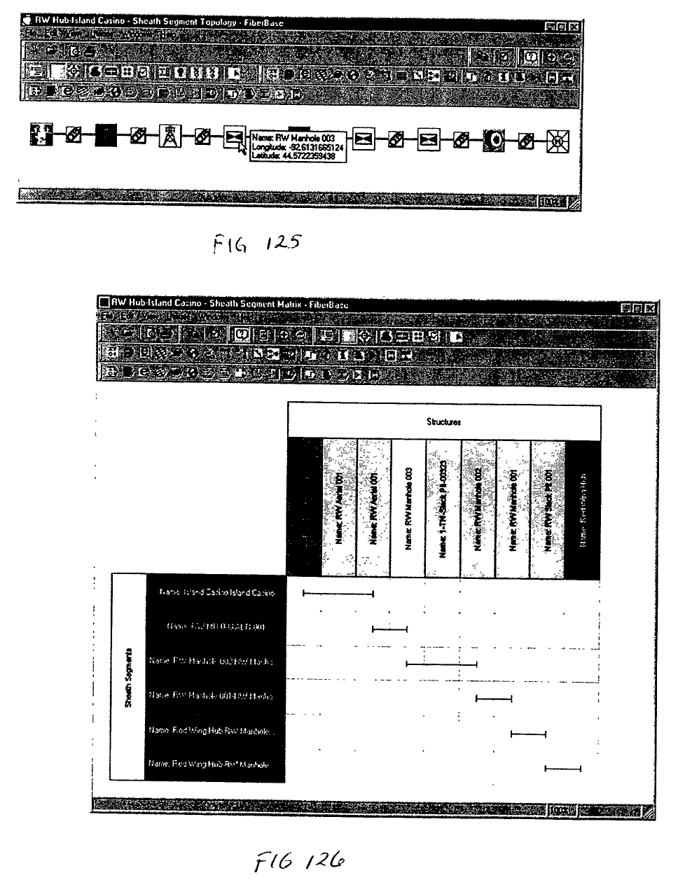

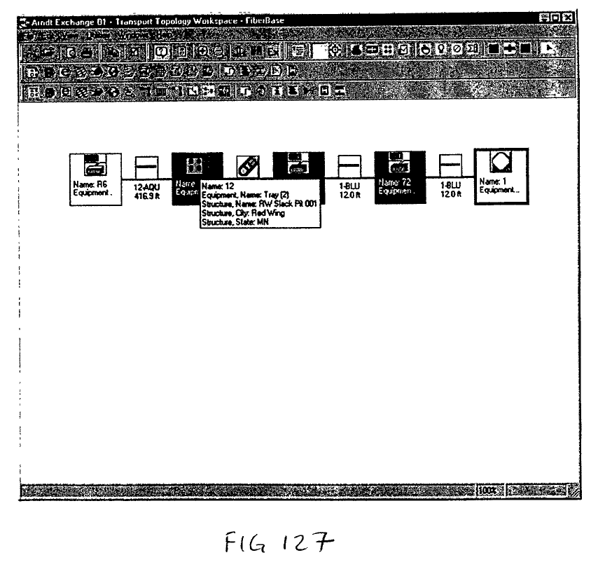

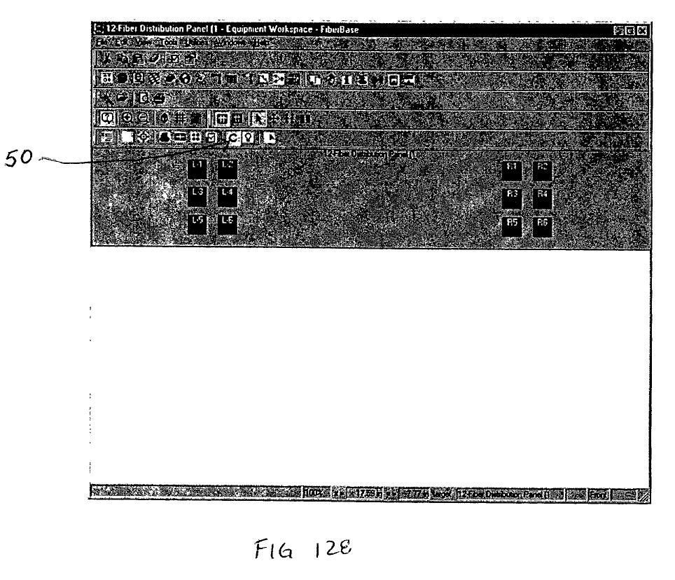

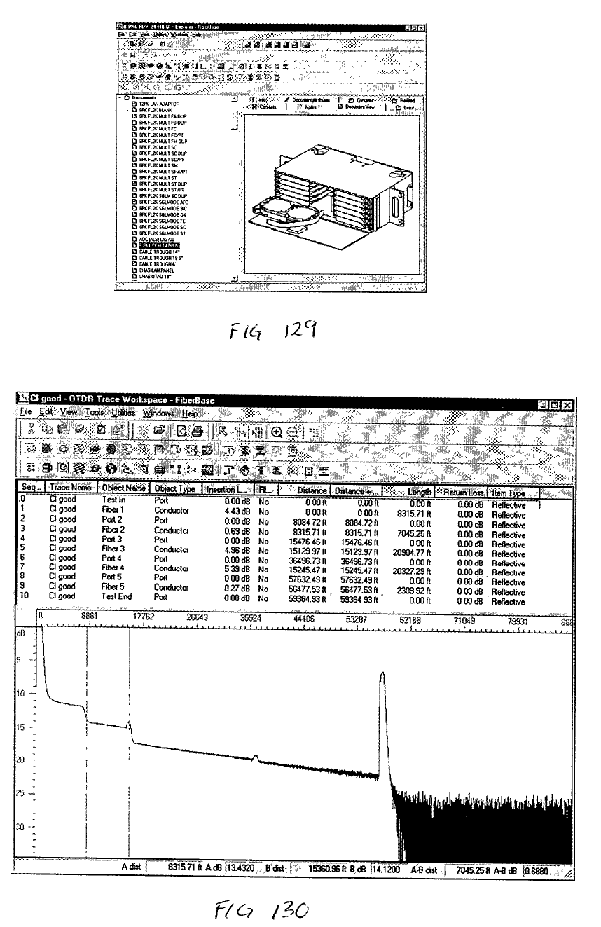

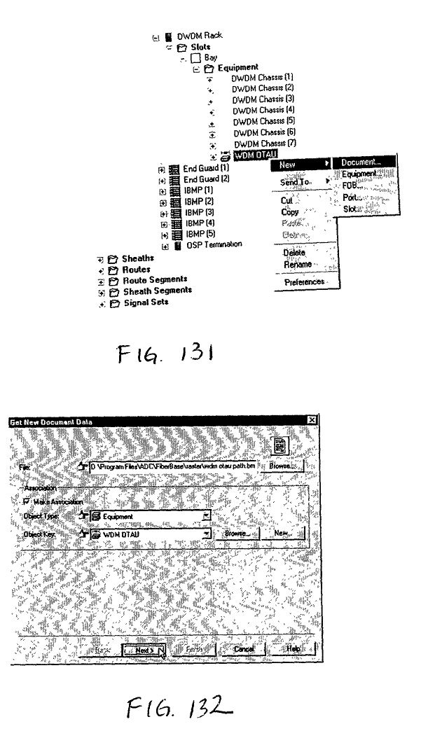

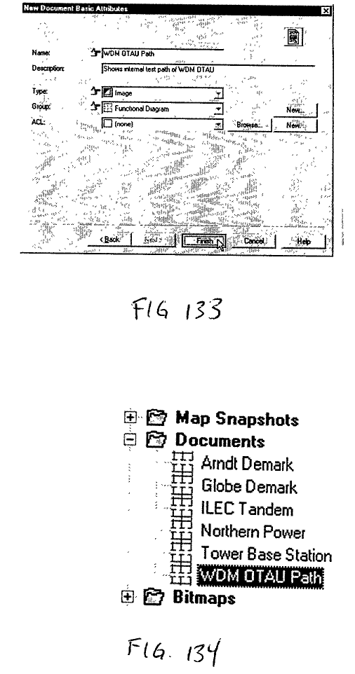

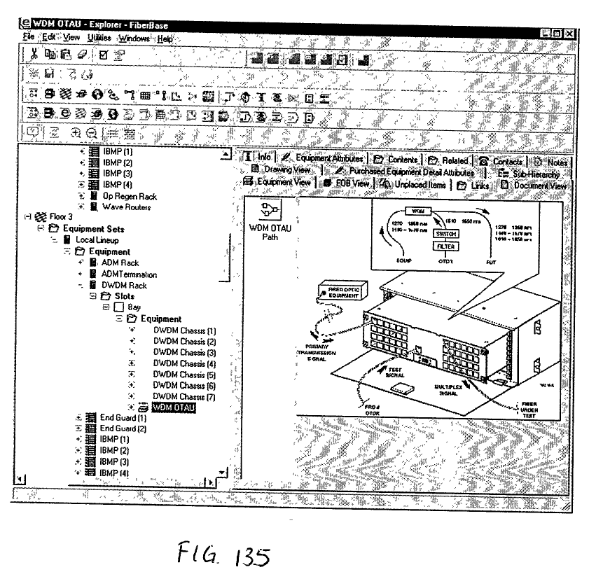

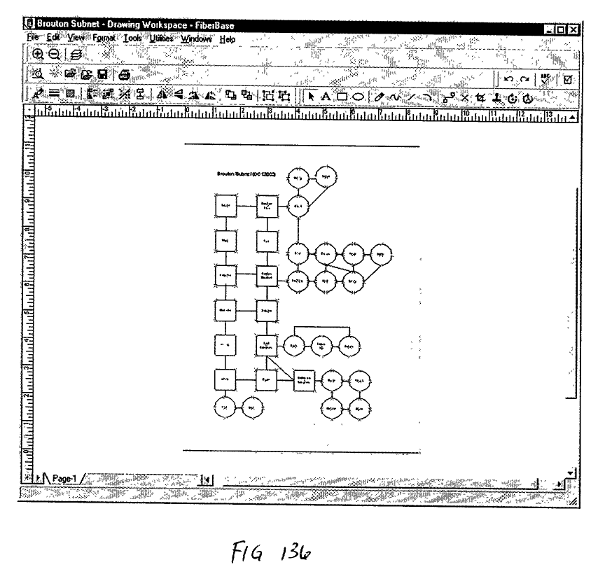

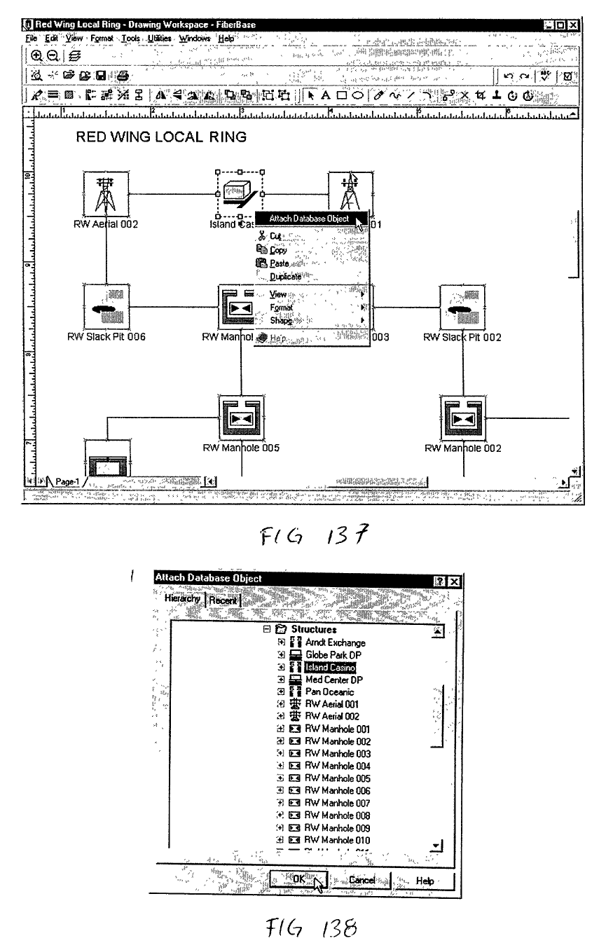

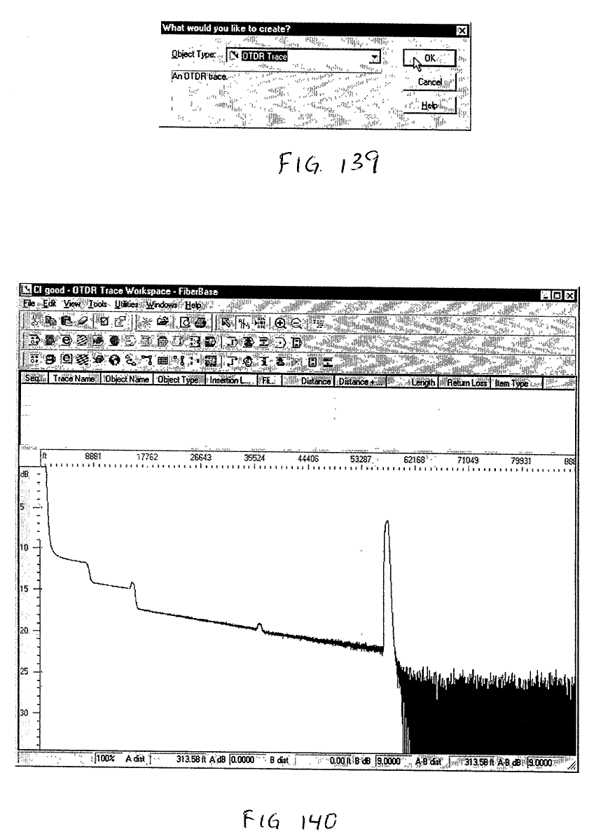

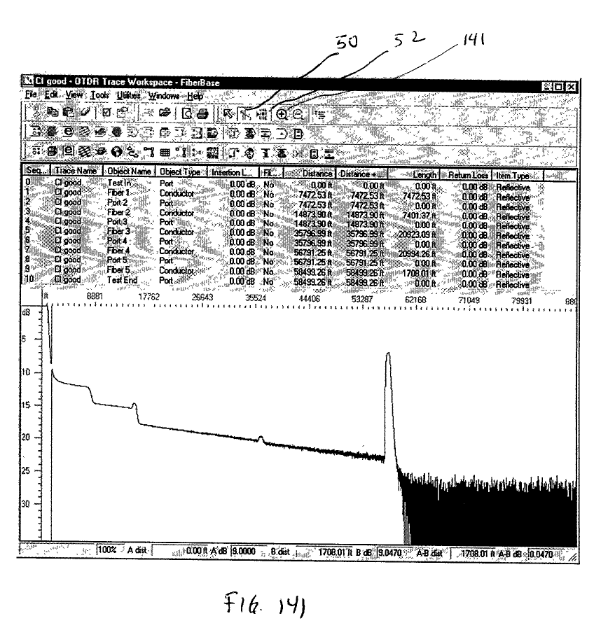

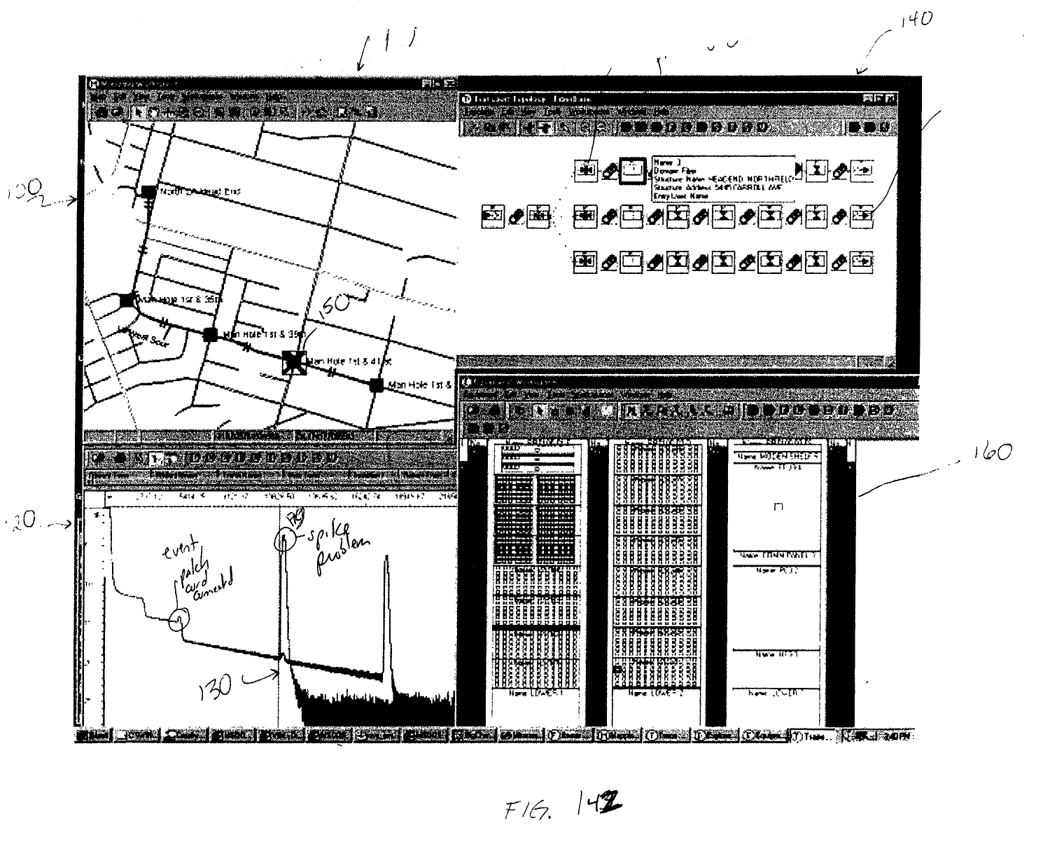

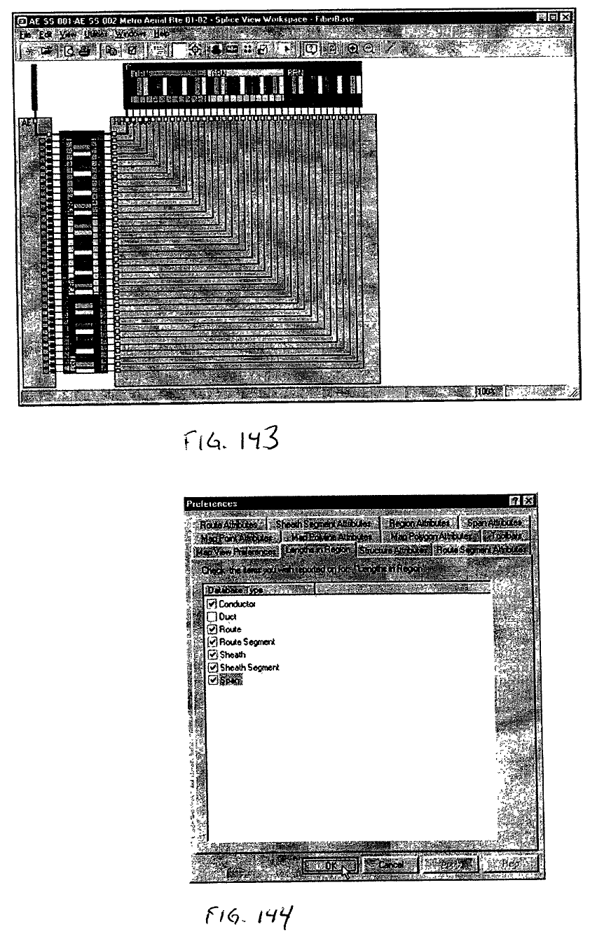

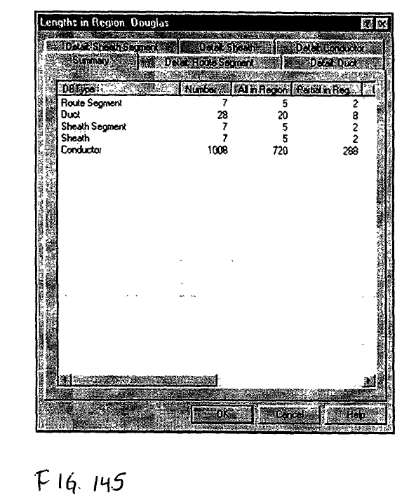

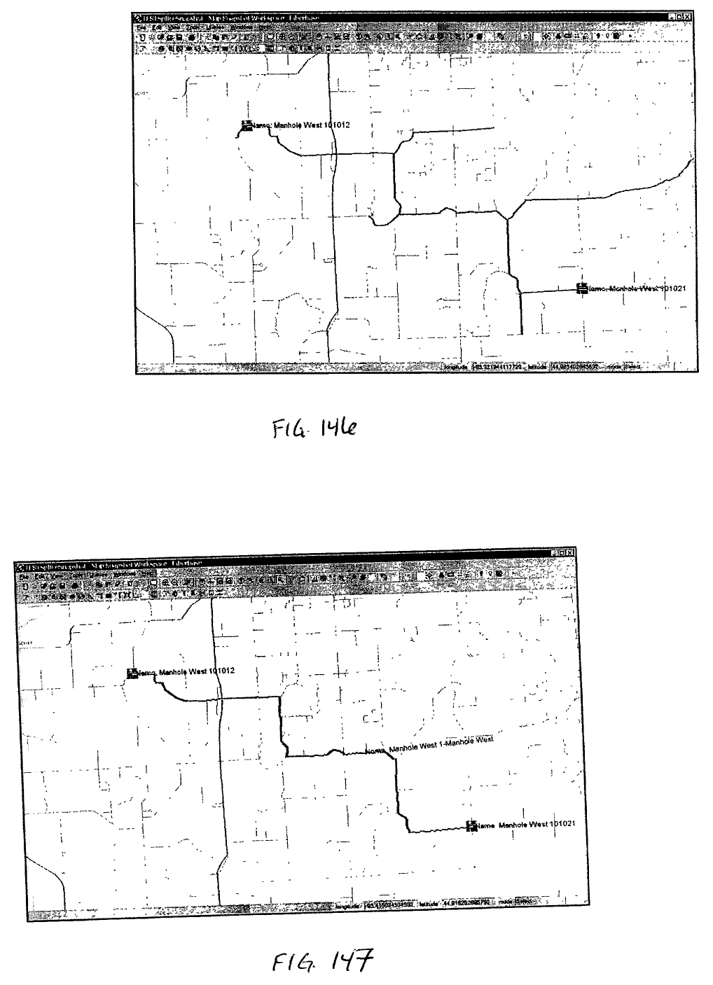

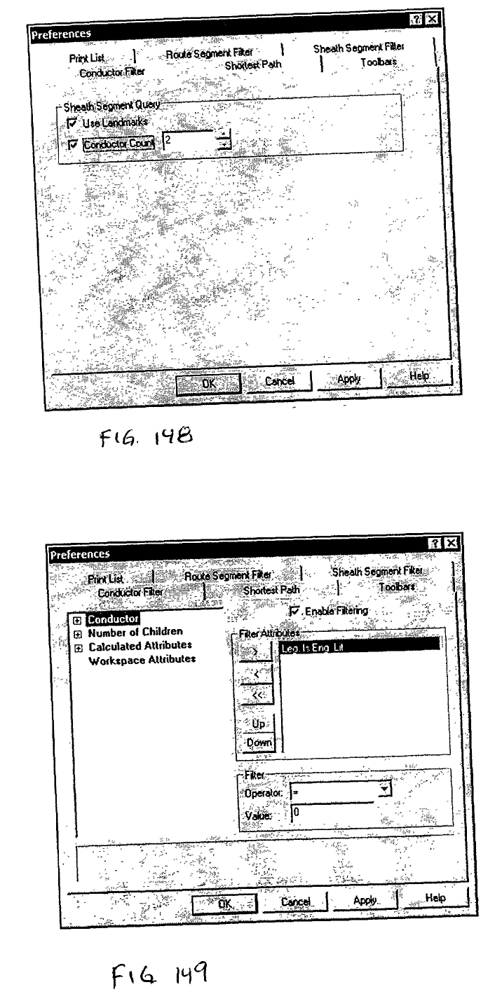

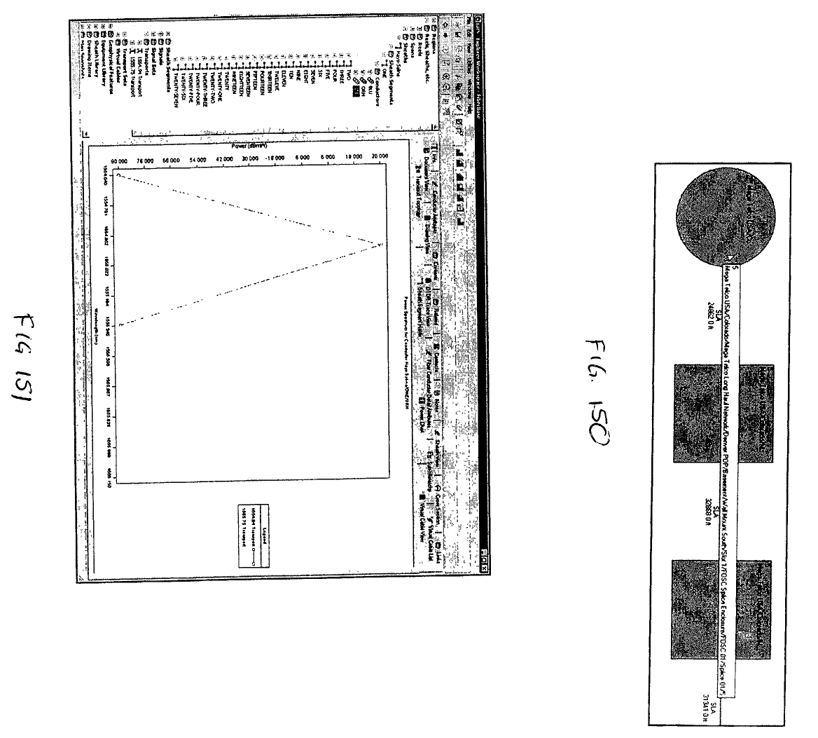

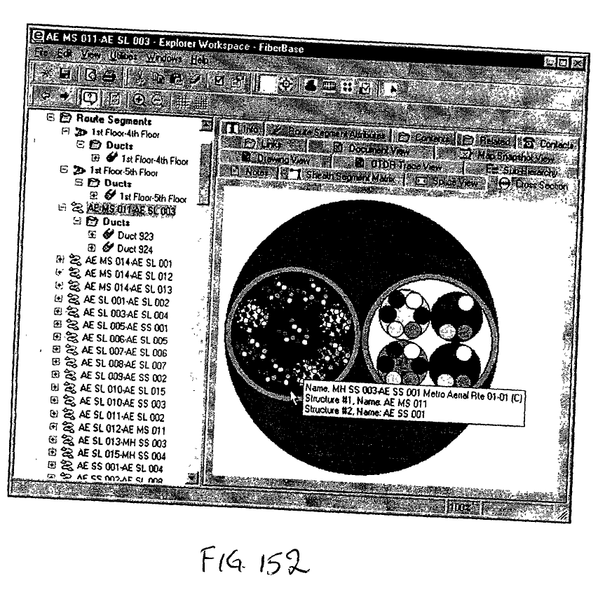

The system has a “Cross Section View” (shown in FIG. 152) that displays for a route segment, duct, sheath segment, binder, or conductor when the object is selected in the Explorer Workspace. A cross section view is a schematic cross section of the physical counterpart of the database object.

To display the cross section view select the object of interest in the Explorer Workspace and click on the Cross Section tab. A cross-section as shown in FIG. 152 appears.

To interpret the cross section view regard each circle shape containing a smaller circle shape as representing a parent-child pair of database objects. For example, the large circle containing may represent a sheath segment and the smaller circle a binder. On a lower scale, a binder circle may contain a number of circles representing conductors. The highest possible level is a route segment which may contain ducts which may contain sheath segments, and so on.

To learn more about the database object represented by any circle shape, right-click on the shape and select Send to from the right-click menu to send the object to another appropriate workspace to obtain additional information.

What is claimed is:

1. A method for analyzing a network infrastructure, the method comprising steps of:
(a) generating a graphical representation of the network infrastructure wherein the graphical representation represents physical locations of the network infrastructure on a geographic map;
(b) testing a portion of the network infrastructure with an OTDR signal to generate an OTDR trace;
(c) displaying the OTDR trace resulting from step (b),
(A) linking a cursor position on the OTDR trace displayed in step (c) with an actual location on the graphical representation generated in step (a).

2. The method of claim 1 further comprising a step of (e) displaying the cursor position linked in step (d) on the graphical representation generated in step (a).

3. A method for analyzing a network infrastructure, the method comprising the steps of:
(a) generating a graphical representation of the network infrastructure wherein the graphical representation represents physical locations of the network infrastructure on a geographic map;
(b) generating a logical representation of the network infrastructure wherein the logical representation represents corrections in the network infrastructure; and
(c) selectively displaying the graphical representation and logical representation.

4. The method of claim 3 further comprising a step (d) of modeling select equipment in the network infrastructure.

5. The method of claim 4 further comprising a step (e) of displaying the select equipment modeled in step (d).

6. A computer program for modeling a network infrastructure, comprising:
(a) a mapping workspace program for generating a graphical representation of the network infrastructure, wherein the graphical representation represents physical locations of the network infrastructure on a geographic map;
(b) a testing program for linking a position of a cursor on the OTDR trace with an actual location on the geographical representation.

7. A computer-readable medium having computer-executable instructions for the method recited in claim 1.

8. A computer-readable medium having computer-executable instructions for the method recited in claim 3.

9. A computer data signal embodied in a carrier wave readable by a computing system and encoding a computer program of instructions for executing a computer program of instruction for executing a computer program performing the method recited in claim 1.

10. A computer data signal embodied in a carrier wave readable by a computing system and encoding a computer program of instructions for executing a computer program of instruction for executing a computer program performing the method recited in claim 3.
